(19) United States
(12) Patent Application Publication
(10) Pub. No.: US 2008/0210952 A1
(43) Pub. Date: Sep. 4, 2008

(54) PHOTO INTERRUPTER, METHOD OF MANUFACTURING THE SAME, AND ELECTRONIC EQUIPMENT USING THE SAME

(76) Inventor: Hideo Wada, Katsuragi-shi (JP)

Correspondence Address: BIRCH STEWART KOLASCH & BIRCH, PO BOX 747, FALLS CHURCH, VA, 22040-0747, US

(21) Appl. No.: 11/877,536

(22) Filed: Oct. 23, 2007

(30) Foreign Application Priority Data
Oct. 24, 2006 (JP) 2006-288405
May 23, 2007 (JP) 2007-136915

(51) Int. Cl. H01L 33/00; H01L 31/12

(52) U.S. Cl. 257/82; 438/25; 257/E33.076; 257/E31.095

(57) ABSTRACT

A photo interrupter has a lead frame assembly that has a lead frame having connector terminals for external connection, a light-emitting mold, a light-receiving mold, and a connector mold. The photo interrupter also has an outer case having a connection section. The connector terminals are adapted to be accommodated in the connector section when the lead frame assembly is accommodated in the outer case. At least one of the outer case or the connector mold is provided with a latching section for latching the connector mold to the outer case. Resin for forming the connector mold may be same as or different from light permeable resin for forming the light-emitting mold and the light-receiving mold.

This nonprovisional application claims priority under 35 U.S.C. §119(a) on Patent Application Nos. 200.6-288405 and 2007-136915 filed in Japan on Oct. 24, 2006 and May 23, 2007, the entire contents of which are hereby incorporated by reference.

### BACKGROUND OF THE INVENTION

The present invention relates to a photo interrupter having an object passage on an optical path from a light-emitting device to a light-receiving device to detect the presence or absence of an object or passage of an object, a method of manufacturing the photo interrupter, and electronic equipment using the photo interrupter.

Conventional photo interrupters having connector terminals include a photo interrupter disclosed in JP 3176496 B2 (‘patent document 1’) and a photo interrupter disclosed in JP 2002-368255 A (‘patent document 2’).

First, patent document 1 will be described. FIGS. 30A and 30B show states in the process of manufacturing a photo interrupter, and FIG. 31 shows a section of the finished product.

As shown in FIG. 30A, a lead frame 1 on which a light-emitting device (not shown) and a light-receiving device (not shown) are bonded and wired and are encapsulated in light permeable resin is bent at suitable positions to allow the light-emitting device and the light receiving device to face each other. In FIG. 30A, the reference numeral 2 denotes encapsulating resin for the light-emitting device, and the reference numeral 3 denotes encapsulating resin for the light-receiving device. During the bending process for bending the lead frame 1, one end (cradle) of the lead frame 1 is cut by tie-bar cutting to form connector coupling sections 4, 5, and 6.

Next, as shown in FIG. 30B, the connector coupling sections 4, 5, and 6 of the lead frame 1 are spot-welded to the pins 8 (see FIG. 31) of a connector 7, thereby connecting the lead frame 1 to the connector 7.

Finally, as shown in FIG. 31, the lead frame 1 connected with the connector 7 is put in an outer case 9, and fixing pins 10 of thermoplastic resin provided in a portion of the outer case 9 where the lead frame 1 is brought into intimate contact with the outer case 9 are inserted in holes (not shown) provided in the lead frame 1, while fixing pins 11 of thermoplastic resin of the outer case 9 provided near the connector coupling sections 4, 5, and 6 (only the connector coupling section 4 is shown in FIG. 31) of the lead frame 1 are inserted between the connector coupling sections 4, 5, and 6. And, the pins 10 and 11 of thermoplastic resin are deformed by heat, thereby fixing the lead frame 1 to the outer case 9. In FIG. 31, the pins 10 and 11 have been deformed by heat, so that they do not have pin shapes before deformed.

Next, patent document 2 will be described. FIG. 32 is a perspective view of photo interrupters in the manufacturing process.

In FIG. 32, capsules 24 each as an outer case having a connector section 23 are formed on a lead frame having outlet terminals 22 in a lead frame sheet 21 by means of insert molding. On the top of each capsule 24, two box-type cases 25 are formed, and on the top face of each of the cases 25, an opening 26 is formed. From the openings 26, a light-emitting device 27 and a light-receiving device 28 fabricated separately are inserted. In portions of the lead frame sheet 21 where the electrode terminals 29 of the light-emitting device 27 and of the light-receiving device 28 are coupled with the lead frame, there are provided connecting structures (not shown) made by making a plurality of cuts so as to intersect each other and then folding down the cut portions.

When light-emitting devices 27 and light-receiving devices 28 are inserted into the corresponding openings 26 of the lead frame sheet 21, the electrode terminals 29 of the light-emitting devices 27 and the light-receiving devices 28 are press-fitted to the associated connection structures of the lead frame sheet 21, and thereby the light-emitting device 27 and the light-receiving device 28 are electrically connected to the lead frame. After that, the lead frame sheet 21 is cut into individual devices to complete photo interrupters.

However, the conventional photo interrupters disclosed in patent document 1 and patent document 2 have problems as described below.

In patent document 1, with respect to the three individual components which are the lead frame 1, the connector 7, and the outer case 9, a process (spot welding, soldering, or the like) of connecting the connector 7 to the lead frame 1, and a process (thermal caulking) of coupling the lead frame 1 and the connector 7 which are connected with each other to the outer case 9 are required. Thus, there is a problem that because the number of components is large, the number of processes required for the assembling of the components is large accordingly.

In patent document 2, the lead frame sheet 21, the connector sections 23, and the capsules 24 are integrally molded, while the light-emitting devices 27 and the light-receiving devices 28 are separate, individual components. Thus, the number of components required is large. Also, the process of press-fitting the light-emitting devices 27 and the light-receiving devices 28 to the lead frame sheet 21 is required. In addition, in order to integrally mold the capsules 24 as outer cases onto each lead frame of the lead frame sheet 21, it is required to keep a region for formation of the capsule 24 on the lead frame, so that the device pitch of the lead frame sheet 21 becomes large. As a result, there is a problem that the number of photo interrupters obtained and manufactured from a fixed length lead frame sheet 21 becomes smaller.

In addition, the photo interrupter of patent document 1 has electrical connection points where the connector coupling sections 4, 5, and 6 of the lead frame 1 are electrically connected with the pins 8 of the connector 7 by spot welding, and the photo interrupter of patent document 2 has electrical connection points where the lead frame is electrically connected with the light-emitting device 27 and the light-receiving device 28 by press-fitting. For this reason, it is feared that the photo interrupters may be decreased in reliability.

### SUMMARY OF THE INVENTION

It is therefore an object of the present invention to provide a photo interrupter allowing reduction in the number of components and simplification of the assembling process to achieve cost reduction, and having no electrical connection points to have high reliability, as well as providing a method of manufacturing the photo interrupter, and electronic equipment using the photo interrupter.

In order to solve the above problem, the present invention provides a photo interrupter, comprising:

a lead frame assembly having a lead frame, a light-emitting device and a light-receiving device which are mounted on the lead frame and each encapsulated in a light permeable resin, and a connector terminal for external connection provided at an end of the lead frame; and

an outer case for accommodating the lead frame assembly so as to be integrated with the lead frame assembly, the outer case being made of light-blocking resin and having a connector section,

wherein the connector terminal is adapted to be accommodated in the connector section when the lead frame assembly is accommodated in the outer case;

wherein the lead frame assembly has a connector mold made of a resin, the connector mold covering at least part of the connector terminal; and

wherein at least any one of the outer case and the connector mold is provided with a latching section for latching the connector mold to the outer case.

According to this configuration, components necessary for the assembling process can be made into two components, that is, a lead frame assembly in which a light-emitting device and a light-receiving device are encapsulated in resin on a lead frame and a connector mold (“mold” herein means a molded part) is also formed, and an outer case having a connector section. Thus, the number of components can be reduced, as compared with the conventional photo interrupters, thereby achieving cost reduction. In addition, when the lead frame assembly is accommodated in the outer case, the connector mold is latched to the outer case by the latching section provided on at least one of the outer case or the connector mold, and thereby the lead frame assembly is fixed to the outer case. Thus, as compared with the conventional photo interrupter disclosed in patent document 1, welding or the like is not required, thereby achieving easy assembly and cost reduction.

In addition, the connector mold is formed on the connector terminal and is latched to the outer case by the latching section, so that the connector terminal can be fixed to the outer case with a sufficient strength. Furthermore, the outer case and the lead frame assembly are produced separately, so that the lead frame sheet does not need space for forming outer cases, meaning that patterns necessary for devices can be arranged as close as possible on the lead frame sheet. Thus, the number of devices obtainable from a lead frame sheet having the same area can be increased, thereby achieving cost reduction. In addition, components handling electrical signals are gathered on only the lead frame so that there are no electrical junction points. Thus, high reliability can be obtained.

In one embodiment, a light-emitting mold having the light-emitting device encapsulated in light permeable resin and a light-receiving mold having the light-receiving device encapsulated in light permeable resin stand erect against a reference surface of the lead frame.

According to this embodiment, a light-emitting mold and a light-receiving mold stand erect against a surface of the lead frame, so that when the light-emitting mold and the light-receiving mold are erected by bending the lead frame, the distance (optical path length) between the light-emitting device and the light-receiving device can be reduced by the height of the optical axis, and the photocoupling efficiency can be thus increased. As a result, a lower-cost light-emitting device having a small amount of emitted light and a lower-cost light-receiving device having a small light-receiving area can be used, thus achieving more cost reduction.

In one embodiment, the light-emitting device and the light-receiving device are mounted on a same surface of the lead frame;

the light-emitting mold and the light-receiving mold stand erect on one side of the reference surface of the lead frame; and

any one of the light-emitting mold and the light-receiving mold has a light reflecting surface for turning direction of an optical path of light emitted from the light-emitting device or direction of an optical path of light to be entered into the light-receiving device.

According to this embodiment, the light-emitting device and the light-receiving device are mounted on the same surface of the lead frame, and the light-emitting mold and the light-receiving mold stand erect on the same side of the surface of the lead frame, so that the light-emitting surface of the light-emitting device and the light-receiving surface of the light-receiving device are directed in the same direction, and do not face each other. However, any one of the light-emitting mold and the light-receiving mold has a light reflecting surface for turning the direction of the optical path of light emitted from the light-emitting device or the direction of the optical path of light to be entered into the light-receiving device to the opposite side, so that the optical axis of the light-emitting device and the optical axis of the light-receiving device can be coupled.

In addition, since the light-emitting device and the light-receiving device are mounted on the same surface of the lead frame, the light-emitting device and the light-receiving device can be mounted on a usual manufacturing line without the need for a special jig or process, and the light-emitting devices and the light-receiving devices can be processed continuously. Thus, the cost of the production facilities can be kept low and the production efficiency can be increased, thereby achieving more cost reduction.

In one embodiment, the light-emitting mold and the light-receiving mold are formed on opposed first and second surfaces of the lead frame, respectively, and stand erect on one side of the reference surface of the lead frame, and the light-emitting device and the light-receiving device face each other.

According to this embodiment, the light-emitting device is mounted on one surface of the lead frame, while the light-receiving device is mounted on another surface of the lead frame, and the light-emitting mold and the light-receiving mold are erected on the same side of the lead frame, so that the light-emitting surface of the light-emitting device and the light-receiving surface of the light-receiving device face each other. Thus, the optical axis of the light-emitting device and the optical axis of the light-receiving device can be coupled easily. In addition, since the light-emitting device and the light-receiving device face each other, the photocoupling efficiency can be increased. Thus, a low-cost light-emitting device and a low-cost light-receiving device can be used, thereby achieving more cost reduction.

In one embodiment, the light-emitting device and the light-receiving device are mounted on a same surface of the lead frame. A lead frame portion associated with the light-emitting mold and a lead frame portion associated with the light-receiving mold are bent from the reference surface of the lead frame such that these molds stand erect on one side of the reference surface of the lead frame. And, the light-emitting device and the light-receiving device face each other.

According to this embodiment, the light-emitting device and the light-receiving device mounted on the same surface of the lead frame face each other in the state that the light-emitting mold and the light-receiving mold stand erect on the same side of the lead frame, so that the optical axis of the light-emitting device and the optical axis of the light-receiving device can be coupled easily. In addition, since the light-emitting device and the light-receiving device are mounted on the same surface of the lead frame, the light-emitting device and the light-receiving device can mounted on a usual production line without the need for a special jig or process, and the light-emitting devices and the light-receiving devices can be processed continuously. Thus, the cost of the production facilities can be kept low and the production efficiency can be increased, thereby achieving more cost reduction.

In one embodiment, connector terminals mechanically separated from each other exist in the connector mold, and the mechanically separated connector terminals are wired by wire bonding and electrically connected with each other.

According to this embodiment, the connector terminals in the connector mold are connected with each other by wire bonding, so that the pin arrangement of the connector terminals can be set freely. Thus, even when the light-emitting device and the light-receiving device having various pad arrangements are used, the pin arrangement of the connector terminals can be set as desired. In particular, when a small photo interrupter is produced, space for routing the wiring of the lead frame is small, so that it becomes difficult to set the pin arrangement of the connector terminals as desired depending on the pad arrangements of the light-emitting device and the light-receiving device. Also in such a case, the pin arrangement of the connector terminals can be set as desired without the need of developing light-emitting devices and light-receiving devices having a modified pad arrangement, thereby achieving cost reduction.

In one embodiment, a connector mold fixing section for fixing the connector mold to the outer case is provided on the outer case on at least one of opposite sides of the connector mold in a direction of extension of the connector terminal.

According to this embodiment, the connector mold is fixed to the outer case by the connector mold fixing section, so that a force applied to the connector terminals when a female connector is extracted from or inserted in the connector terminals is suppressed by the connector mold fixed to the outer case, and is not applied to the lead frame on which the light-emitting device and the light-receiving device are mounted. Thus, the lead frame can be prevented from deforming, thereby improving the reliability.

In one embodiment, the photo interrupter further includes a lead frame fixing column which is formed on the outer case and extends in a direction orthogonal to a direction of extension of a main body of the lead frame to fix the main body of the lead frame.

According to this embodiment, the main body of the lead frame is fixed by the lead frame fixing column formed on the outer case, so that a force applied to the connector terminals at extraction or insertion of a female connector is suppressed by the lead frame fixing column formed on the outer case, and is not applied to the lead frame on which the light-emitting device and the light-receiving device are mounted. Thus, the lead frame can be prevented from deforming, thereby improving the reliability.

In one embodiment, the photo interrupter further includes a groove-like notch formed in the connector mold, and a connector mold latching section shaped like a column which is provided on an inner surface of the outer case and is engaged with the notch to latch the connector mold.

According to this embodiment, the connector mold latching section shaped like a column provided on the inner surface of the outer case is engaged with the notch shaped like a groove formed in the connector mold to latch the connector mold, so that a force applied to the connector terminals at extraction or insertion of a female connector is suppressed by the connector mold latching section provided on the outer case, and is not applied to the lead frame on which the light-emitting device and the light-receiving device are mounted. Thus, the lead frame can be prevented from deforming, thereby improving the reliability.

In one embodiment, the light-emitting device and the light-receiving device are mounted on a same surface of the lead frame. And, the photo interrupter further comprises:

a first reflecting surface which is provided on an inner surface of the outer case in a position facing the light-emitting device for reflecting light emitted from the light-emitting device toward the light-receiving device, and a second reflecting surface which is provided on the inner surface of the outer case in a position facing the light-receiving device for reflecting light from the first reflecting surface to the light-receiving device; and

an optical axis of the light-emitting device and an optical axis of the light-receiving device are coupled by the first reflecting surface and the second reflecting surface.

According to this embodiment, a first reflecting surface reflecting light emitted from the light-emitting device toward the light-receiving device, and a second reflecting surface reflecting light from the first reflecting surface to the light-receiving device are provided on the inner surface of the outer case, and the optical axis of the light-emitting device and the optical axis of the light-receiving device are coupled by the first reflecting surface and the second reflecting surface, so that it is not necessary to erect the light-emitting mold and the light-receiving mold against a surface of the lead frame. Thus, the production process can be simplified, thereby achieving cost reduction.

In one embodiment, the light-emitting device and the light-receiving device are mounted on a same surface of the lead frame. And, the outer case is provided with an emitted light refractor in a position facing the light-emitting device for refracting light emitted from the light-emitting device to direct the light to an object to be detected, and an incident light refractor in a position facing the light-receiving device for refracting light reflected by the object to be detected to direct the light to the light-receiving device.

According to this embodiment, because the outer case is provided with the emitted light refractor refracting light emitted from the light-emitting device to direct the light to an object to be detected and the incident light refractor refracting light reflected by the object to direct the light to the light-receiving device, it is not necessary to erect the light-emitting mold and the light-receiving mold against the reference surface of the lead frame. Thus, the production process can be simplified, thereby achieving cost reduction.

The resin which the connector mold is made of may be a same light permeable resin as or a different resin from the light permeable resin encapsulating the light-emitting device and the light-receiving device.

In one embodiment, the resin which the connector mold is made of is different from the light permeable resin encapsulating the light-receiving device and the light-emitting device. Thus, resins most suitable for functions required for molds (i.e., molded parts) to be used can be selected as follows. For example, as a molding resin for the light-emitting mold and the light-receiving mold, selection can be made of a light permeable resin which has a high fluidity not so as to cut gold wires connecting the light-receiving device and the light-emitting device with the lead frame and which is pervious to light emitted from the light-emitting device. Such light permeable resin may be an epoxy resin or a silicone resin. As the epoxy resin, one that transmits infrared light but blocks visible light may be preferably selected because infrared LEDs are generally used as light-emitting devices. Furthermore, as the molding resin for the connector mold, a resin having a high mechanical strength can be selected. Examples of such a resin include PPS (polyphenylene sulfide) and liquid crystal polymers. In addition, a path for supplying the light permeable resin when forming the light-receiving mold and the light-emitting mold, and a path for supplying the molding resin when forming the connector mold are provided independent of each other, and thereby both of the paths can be made short and simple to stabilize the productivity.

In one embodiment, fillers are mixed in the resin which the connector mold is made of.

According to this embodiment, as the resin for the connector mold for which a high mechanical strength is required, resin in which fillers are mixed is used. Thus, the mechanical strength of the resin for the connector mold can be increased, and thereby the reliability of the photo interrupter can be more improved. Glass fibers, carbon fibers, or the like can be used as the fillers.

The present invention also provides a method of manufacturing the photo interrupter, comprising steps of:

mounting a light-emitting device and a light-receiving device on a lead frame which is formed with connector terminals and performing predetermined wiring for the light-emitting device and the light-receiving device;

forming a light-emitting mold and a light-receiving mold by encapsulating the light-emitting device and the light-receiving device on the lead frame in a light permeable resin;

forming a connector mold by encapsulating part of the connector terminal in a resin;

forming an outer case having a connector section at an end thereof by injection molding; and

inserting in the outer case the lead frame on which the light-emitting mold, the light-receiving mold, and the connector mold are formed such that the connector terminals of the lead frame are positioned in the connector section of the outer case, thereby accommodating the lead frame in the outer case,

wherein any one of said step of forming an outer case and said step of forming a connector mold comprises forming a latching section for latching the connector mold to the outer case; and

wherein the connector mold is latched and fixed, when accommodating the lead frame in the outer case, to the outer case by the latching section formed on at least one of the outer case or the connector mold.

According to this configuration, components necessary for the assembling process can be made two components, that is, a lead frame on which a light-emitting device and a light-receiving are encapsulated in resin and a connector mold is formed, and an outer case having a connector section, so that the number of components can be reduced as compared with the conventional photo interrupters, thus achieving cost reduction. In addition, when the lead frame is accommodated in the outer case, the connector mold is latched to the outer case by a latching section provided on at least any one of the outer case and the connector mold, and the lead frame is thus fixed to the outer case. Thus, as compared with the conventional photo interrupter disclosed in patent document 1, welding or the like is not required, thereby achieving easy assembly and cost reduction.

In one embodiment, the step of mounting a light-emitting device and a light-receiving device and performing predetermined wiring comprises mounting a plurality of light-emitting devices and a plurality of light-receiving devices on a lead frame sheet in which two or more sets of connector terminals are formed and performing predetermined wiring for the light-emitting devices and the light-receiving devices. The step of forming a light-emitting mold and a light-receiving mold comprises forming light-emitting molds and light-receiving molds for the respective light-emitting devices and the respective light-receiving devices. The step of forming a connector mold comprises forming connector molds for the respective sets of connector terminals. And, the method further comprises cutting tie bars placed at least on the peripheries of the light-emitting molds and the light-receiving molds, and cutting tie bars by which devices each having the light-emitting mold, the light-receiving mold, the connector mold, and the connector terminals are connected and fixed to a main body of the lead frame sheet to divide the lead frame sheet into the individual devices. The connector terminals are formed into their final shapes in any one of the step of cutting tie bars placed at least on the peripheries of the light-emitting molds and the light-receiving molds or the step of cutting tie bars by which devices each are connected and fixed to the main body of the lead frame sheet to divide the lead frame sheet into the individual devices.

In this embodiment, since the connector terminals are shaped into their final shapes, namely forming of the connector terminals is performed in the process of cutting tie bars, the connector terminals of various shapes and various terminal intervals can be formed only by changing the cutting die. Thus, the connector terminals of two or more patterns can be made from the same lead frame sheet. Accordingly, the cost necessary for making lead frames of two or more shapes can be reduced by sharing the use of the lead frame sheet, thus achieving more cost reduction.

In one embodiment, the method further comprises a plating step of covering the connector terminals with metal performed after the step of cutting tie bars including forming the connector terminals into their final shapes.

According to this embodiment, the reliability such as the anticorrosiveness can be improved by covering with metal the connector terminals having bared cut surfaces. In addition, the reliability of junction of the connector terminals can be improved by covering the connector terminals with the same kind of metal as the female connector.

The step of forming a light-emitting mold and a light-receiving mold and the step of forming a connector mold may be performed together in a same process by using a same light permeable resin material. Alternatively, the step of forming a light-emitting mold and a light-receiving mold and the step of forming a connector mold are performed separately by using different resin materials.

In one embodiment, the light-emitting mold and the light-receiving mold are made of resin different from that for the connector mold in a process different from that for the connector mold. Thus, resins most suitable for functions required for molds to be used can be selected to form the molds. In addition, supply paths for the resins can be made short and simple to stabilize the productivity.

In one embodiment, the step of forming a light-emitting mold and a light-receiving mold and the step of forming a connector mold are performed in a same process, in which process a light permeable resin supplied from a first resin supply source is used for the light-emitting mold and the light-receiving mold, while a resin different from the light permeable resin supplied from a second resin supply source is used for the connector mold.

According to this configuration, the light-emitting mold and light-receiving mold and the connector mold are formed in the same process using different resins. Thus, resins most suitable for functions required for the molds (molded parts) to be used can be selected to form the molds in one process. In addition, the resins are supplied from different resin supply sources, and thereby supply paths for those resins can be made short and simple to stabilize the productivity.

Electronic equipment according to the present invention includes the photo interrupter of the present invention.

Because the photo interrupter that the electronic equipment uses consists of a few components, has a lead frame and an outer case capable of being assembled in a simple process, and is reliable because of having no electrical junction points, the electronic equipment, such as a copying machine or a printer, can smoothly carry out detection of the presence or absence of a paper, detection of an edge of a paper, and so on. In addition, when a photo interrupter is used in which the connector mold is made of resin different from that for the light-emitting mold and the light-receiving mold to increase the mechanical strength of the connector mold, the reliability of the electronic equipment can be more increased.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIGS. 1A, 1B, and 1B are a top view, a side view, and a front view, respectively, showing the configuration of a photo interrupter according to a first embodiment of the present invention;

FIG. 2A is a cross-sectional view taken along the line A-A′ of FIG. 1A;

FIG. 2B is a cross-sectional view taken along the line B-B′ of FIG. 1A;

FIG. 2C is an enlarged view of C portion in FIG. 2A;

FIGS. 3A and 3B are cross-sectional views showing the structures of connector mold latching sections which are different from that in FIG. 2B;

FIGS. 4A, 4B, and 4C are a top view, a side view, and a front view, respectively, showing a structure for preventing breakage caused by extraction or insertion of a female connector, which is different from that in FIG. 2;

FIG. 5 depicts a lead frame fixing column;

FIG. 6 shows an example of a lead frame pattern;

FIG. 7 shows the state that a light-emitting device and a light-receiving device are bonded to a lead frame having a pattern shown in FIG. 6 by die bonding technique;

FIGS. 8A and 8B are a top view and a side view, respectively, showing the state that the bases of the light-emitting device, light-receiving device, and connector terminals are encapsulated in resin;

FIG. 9 is a top view of a lead frame in the state after tie-bar cutting;

FIG. 10 is a top view of a lead frame in the state that a light-emitting mold and a light-receiving mold have been erected;

FIGS. 11A and 11B are a top view and a side view, respectively, showing a lead frame component obtained by cutting the periphery of a lead frame in FIG. 9;

FIGS. 12A and 12B are bottom views of a first component and a second component, respectively;

FIG. 13 shows a manner in which a first component is being inserted in a second component;

FIGS. 14A and 14B are top views of lead frames in which different sets of connector terminals are formed;

FIGS. 15A and 15B depict a wire bridge function;

FIGS. 16A and 16B are side views in different states of the first component of a photo interrupter which is different from that in FIG. 2B;

FIG. 17 is a cross-sectional view showing the state that the first component shown in FIGS. 16A and 16B is engaged with a second component;

FIGS. 18A, 18B, and 18C are a side view, a front view, and a side view of the first component of a photo interrupter which is different from that in FIG. 2 or 16;

FIGS. 19A and 19b are a top view and a cross-sectional view, respectively, showing the configuration of a photo interrupter according to a second embodiment of the present invention;

FIG. 20 shows the configuration of a photo interrupter according to a third embodiment of the present invention;

FIG. 21 shows connector terminal arrangement applicable to photo interrupters according to the embodiments of the present invention;

FIG. 22 shows resin supply paths through which the same molding resin is to be supplied to portions to be encapsulated in the resin, of a plurality of lead frame sheets in one molding process step;

FIGS. 23A, 23B, and 23B are perspective views of the outer case, the lead frame, and the assembly consisting of the outer case and the lead frame of a photo interrupter according to a fourth embodiment of the present invention;

FIG. 24 shows an example of a pattern of a lead frame sheet in which single-piece lead frames are arranged like a matrix;

FIG. 25 depicts a method of forming connector molds on the lead frame sheet shown in FIG. 24;

FIG. 26 depicts a method of forming light-emitting molds and light-receiving molds on the lead frame sheet shown in FIG. 24;

FIG. 27 shows the state that a female connector is extracted from or inserted in the connector section of the photo interrupter in FIG. 23;

FIG. 28 is an explanatory view that depicts forces which act on the inside of the connector mold in FIG. 27;

FIG. 29 depicts a method of forming light-emitting molds, light-receiving molds, and connector molds on lead frame sheets in one process step;

FIGS. 30A and 30B depict the connector coupling structure of a conventional photo interrupter;

FIG. 31 is a longitudinal sectional view showing the state that the connector and the lead frame coupled to each other shown in FIG. 30A are accommodated in an outer case; and

FIG. 32 depicts assembly of a conventional photo interrupter different from that in FIG. 30.

### DETAILED DESCRIPTION OF THE INVENTION

The present invention will be described in detail below with reference to the embodiments shown in the figures.

### First Embodiment

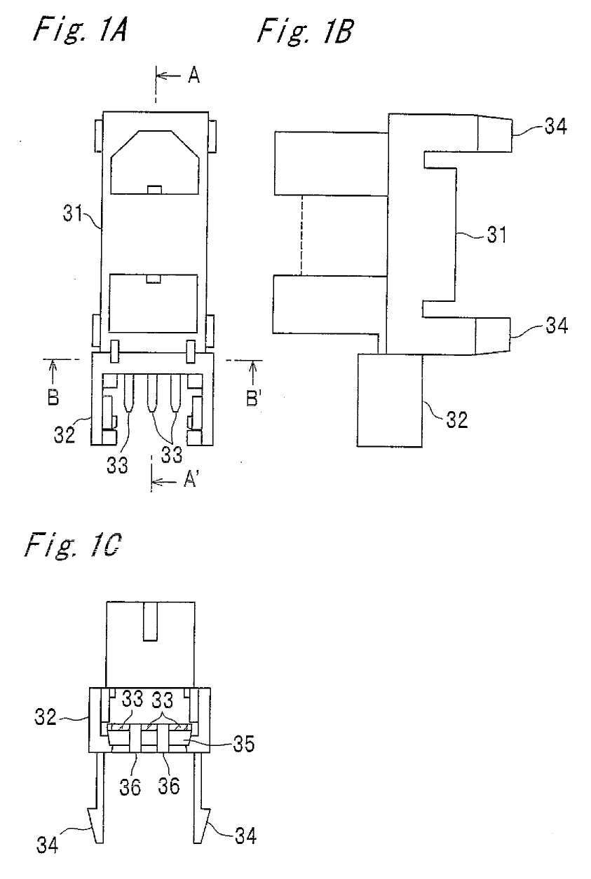

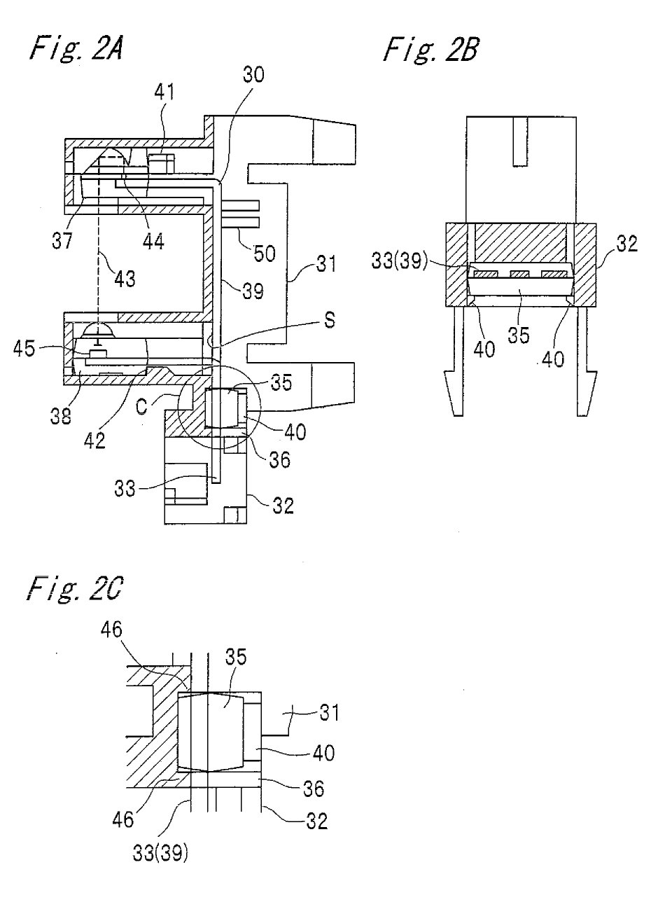

FIGS. 1A to 1C and FIGS. 2A and 2B show the configuration of a photo interrupter of a first embodiment, wherein FIG. 1A is a top view, FIG. 1B is a side view, and FIG. 1C is a front view. Also, FIG. 2A is a cross-sectional view taken along the line A-A′ of FIG. 1A. FIG. 2B is a cross-sectional view taken along the line B-B′ of FIG. 1A. FIG. 2C is an enlarged view of C portion in FIG. 2A.

At first, the outline of this photo interrupter will be described briefly referring to FIGS. 1A and 1B. As shown in FIGS. 1A and 1B, an outer case 31 is formed integrally with a connector section 32, and connector terminals 33 are formed in the connector section 32. The connector section 32 is formed in such a shape that the connector terminals 33 can be seen from the top as shown in FIG. 1A, but cannot be seen from the lateral sides as shown in FIG. 1B. However, the shape of the connector section 32 is not limited to this shape, and there is particularly no limit to the shape as long as it corresponds to a female connector to be connected to the connector section.

On the four corners of the bottom of the outer case 31, hooks 34 for attachment to an external substrate (not shown) or external equipment are provided. Furthermore, as shown in FIG. 1C, a connector mold 35, connector terminals 33, and a first connector mold fixing section 36 are formed on the front face of the connector section 32.

Next, with reference to FIGS. 2A to 2C, the internal structure of this photo interrupter will be described. As shown in FIG. 2A, this photo interrupter consists of two components, that is, an outer case 31 integrally formed with a connector section 32 from light-blocking resin, and a lead frame assembly having a lead frame 39, a connector mold 35, a light-emitting mold 37, and a light-receiving mold 38. The two components are fixed at three points by the connector mold 35 and a connector mold latching section 40, the light-emitting mold 37 and a light-emitting mold latching section 42, and the light-receiving mold 38 and a light-receiving mold latching section 42.

The light-emitting mold 37 and the light-receiving mold 38 stand erect against a surface (reference surface) S of the lead frame 39. In such a manner, the optical axis 43 is provided at a predetermined height, and the distance between the light-emitting device and the light-receiving device (optical path length) is decreased at the height of the optical axis 43 to increase the photocoupling efficiency. In FIG. 2A, the reference numeral 44 denotes a light-emitting device, and the reference numeral 45 denotes a light-receiving device.

Furthermore, the bases of the connector terminals 33 are fixed to the connector mold 35, and the connector mold 35 is fixed to the outer case 31 by the connector mold latching section 40. Thus, the connector terminals 33 are fixed to the outer case 31 with a sufficient strength. For this reason, when a female connector to be connected to the connector section 32 is inserted from external equipment, even if the female connector is twisted, deformation and/or breakage are not produced on the connector terminals 33 and/or the connector section 32. The structure of the connector mold 35 and the connector mold latching section 40 are, as shown in FIG. 2B, such that the connector mold latching section 40 formed between the main body of the outer case 31 and the connector section 32 holds the bottom corners of the connector mold 35, thereby fixing the connector 35.

In this embodiment, the lead frame 39 on which the connector mold 35, the light-emitting mold 37, and the light-receiving mold 38 are formed is pushed in the outer case 31 from underneath, and thereby the connector mold 35, the light-emitting mold 37, and the light-receiving mold 38 are engaged with and latched by the corresponding connector mold latching section 40, light-emitting mold latching section 41, and light-receiving mold latching section 42 by taking advantage of the elasticity of the light permeable resin which the molds are made of and the elasticity of the light-blocking resin which the latching sections are made of. As an example of the structures of the latching sections 40 to 42, engaging structures are shown. However, press-fitting, adhesion, or the like may be applied, and there are no restrictions on the latching method.

As shown in FIG. 2C in an enlarged manner, the connector section 32 is formed with a first connector mold fixing section 36 for holding the connector mold 35 from the connector section 32 side. Furthermore, a second connector mold fixing section 46 for holding the connector mold 35 between the connector section 32 and the main body of the outer case 31 is formed on the main body of the outer case and the connector section 32. When the female connector is extracted from or inserted to the connector section 32, the connector terminals 33 (i.e. the lead frame 39) receives a pulling force in the direction of extraction or a pushing force in the direction of insertion. For this reason, the pulling force and the pushing force are transferred to the first connector mold fixing section 36 and the second connector mold fixing section 46 through the connector mold 35, and are suppressed by the first connector mold fixing section 36 and the second connector mold fixing section 46. Thus, it can be prevented that both of the forces applied to the lead frame are applied to the inside of the photo interrupter. As a result, the photo interrupter can be prevented from being broken so that the light-emitting mold 37 and the light-receiving mold 38 standing erect from the reference surface of the lead frame 39 are deformed and the position of the optical axis 43 is thus shifted.

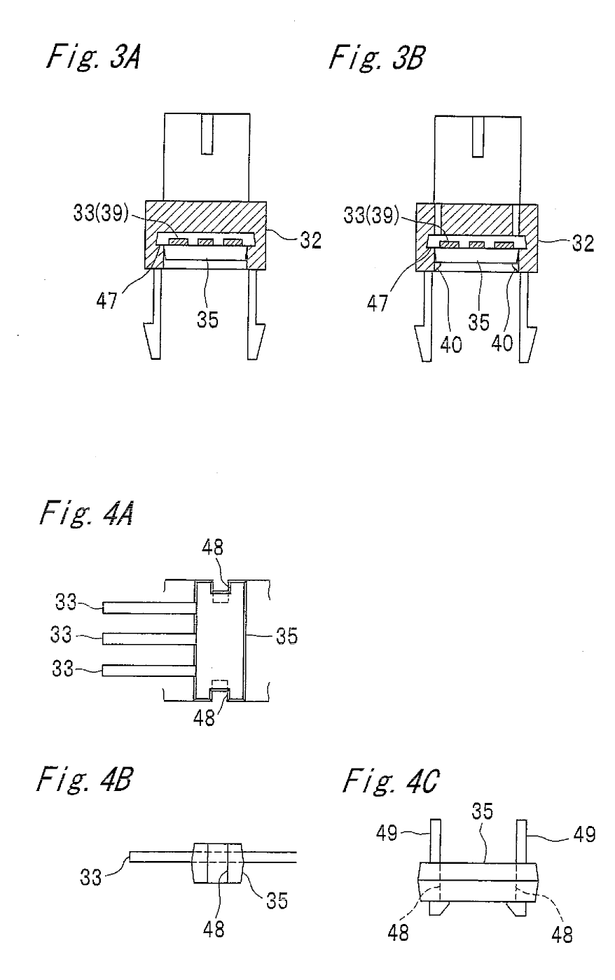

FIG. 2B shows that a connector mold latching section 40 is provided between the main body of the outer case 31 and the connector section 32. However, there is not limit to this, and as shown in FIG. 3A, a latching section 47 shaped like an “eave” may be provided on the connector mold 35. Furthermore, as show in FIG. 3B, both the latching section 40 between the main body of the outer case 31 and the connector section 32 and the latching section 47 on the connector mold 35 may be provided.

FIGS. 4A to 4C show a structure for preventing breakage of the photo interrupter caused by a pulling force and a pushing force applied to the lead frame 39 at insertion and extraction of the female connector, respectively, which structure is different from that in FIG. 2. FIG. 4A is a top view, FIG. 4B is a side view, and FIG. 4C is a front view. In FIGS. 4A to 4C, components unnecessary for description are omitted for simple description. As shown in FIGS. 4A and 4B, groove-like notches 48 extending in the vertical direction are formed on both sides of the connector mold 35. Furthermore, as shown in FIG. 4C, connector mold latching sections 49 each having a protrusion shaped like a column extending in the vertical direction are formed on the surfaces (not shown) of the connector mold 35 accommodating section (not shown) provided in the outer case 31, which surfaces face the notches 48 of the connector mold 35. When the lead frame 39 is inserted in the outer case from underneath, the connector mold latching sections 49 of the outer case 31 are inserted in the notches 48 formed in the connector mold 35 on the lead frame 39 to allow the connector mold latching sections 49 to be engaged with the notches 48.

As a result, even if the connector terminals 33 (i.e. the lead frame 39) are pulled or pushed by extraction or insertion of the female connector, the pulling force or the pushing force is transferred to the connector mold latching sections 49 through the connector mold 35, and are suppressed by the connector mold latching sections 49. Thus, both of the forces applied to the lead frame 39 can be prevented from being applied to the inside of the photo interrupter. As a result, the photo interrupter can be prevented from damages such as deformation of the light-emitting mold 37 and the light-receiving mold 38 on the lead frame 39.

In addition, as shown in FIG. 2A, two lead frame fixing columns 50 extending in the vertical direction are formed in the outer case 31. FIG. 5 is a top view depicting the lead frame fixing columns 50 in detail. However, for simple description, part of the outer case 31 is omitted to allow the lead frame 39, connector mold 35, light-emitting mold 37, and light-receiving mold 38 inside to be seen. This can be said also for other figures in the following description.

As shown in FIG. 5, a lead frame 39 which electrically connects the light-emitting mold 37 to the light-receiving mold 38 is formed inside the outer case 31. Furthermore, the lead frame 39 has a frame line (test pad) 51 near the light-emitting mold 37. The frame line 51 is formed so as to extend in a direction orthogonal to the direction of extension of the connector terminals 33. The lead frame fixing columns 50 are formed so as to hold the frame line 51 therebetween, and even if a force is applied to the lead frame 39 at extraction or insertion of the female connector 39, the lead frame 39 can be prevented from being displaced because the frame line 51 (i.e. lead frame 39) is held between the lead frame fixing columns 50. As a result, the photo interrupter can be prevented from being broken by deformation of the lead frame.

In this embodiment, a lead frame having the frame line (test pad) 51 as shown in FIG. 5 is described as an example of a pattern of the lead frame held between the lead frame fixing columns 50. However, in the present invention, there is not limited to this structure, and there is also no limit to the shape and position of the frame line as long as it is structured so as to be able to absorb a force applied to the lead frame 39 in the direction of extraction or insertion of the female connector.

Described above are two or more structures which prevent the lead frame 39 from being deformed by a pulling force or a pushing force applied to the lead frame 39 at extraction or insertion of the female connector. However, it is of course not necessary to employ all of the structures, and some of them may be selected as necessary in consideration of use conditions and the like.

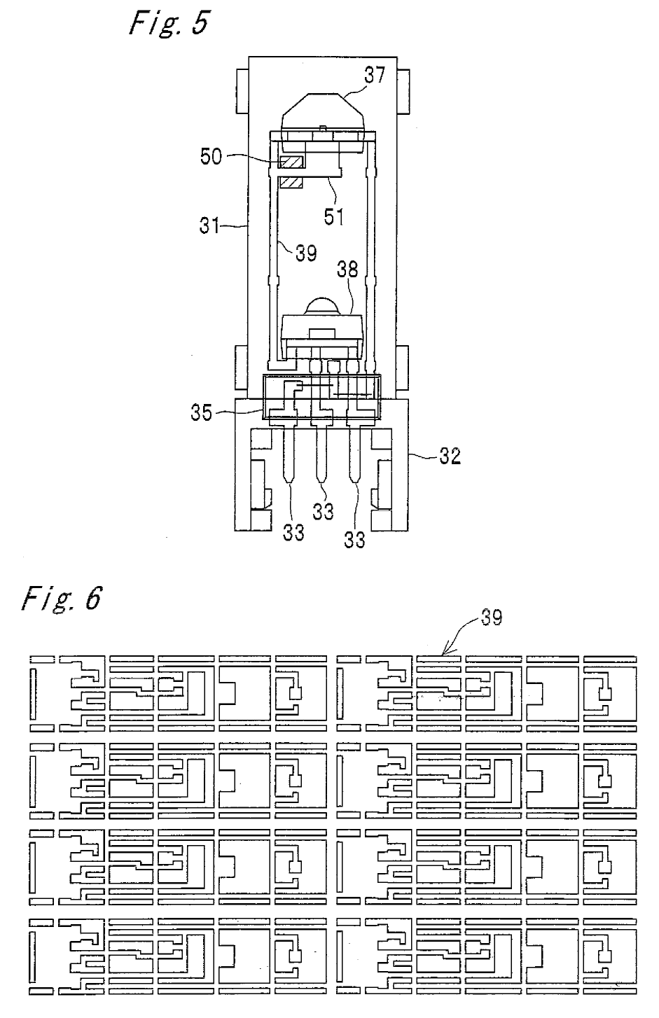

Next, the detail structure of the photo interrupter of this embodiment will be described with reference to FIGS. 6 to 12. In the following description, a lead frame assembly 30 in which molds such as the connector mold 35, the light-emitting mold 37, and the light-receiving mold are formed on the lead frame 39 is referred to as a “first component”, and the outer case 31 formed integrally with the connector section 32 is referred to as a “second component”.

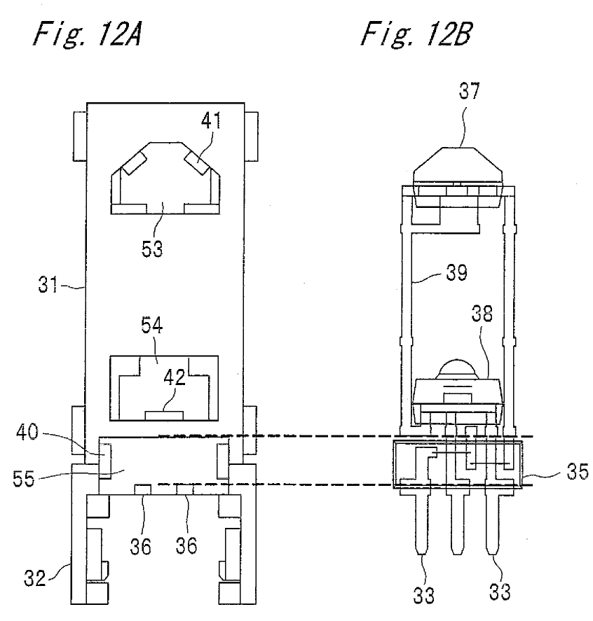

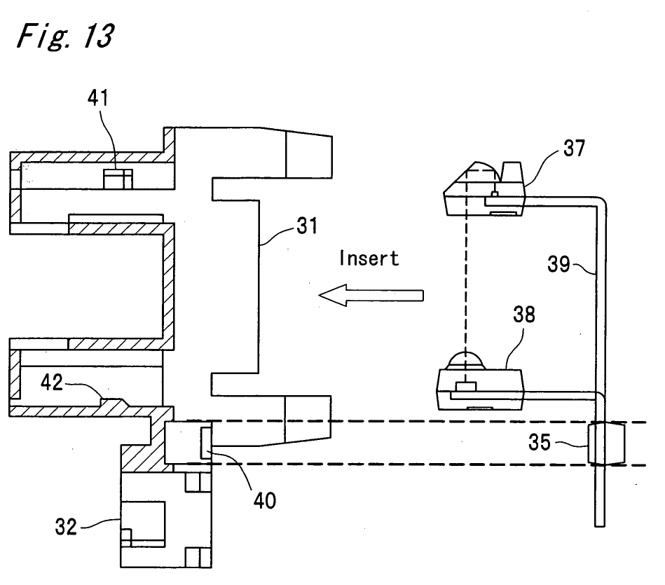

FIGS. 6 to 11 show an example of the structure of the first component. FIGS. 12 and 13 depict the method of assembling the second component and the first component.

At first, the first component will be described. FIG. 6 shows an example of a pattern of a lead frame sheet 39 from which the substrate of the first component will be made. In one lead frame sheet 39 as shown in FIG. 6, a predetermined number of devices are arranged and formed. Since the devices are of the same structure in each manufacturing process, the following description is made on the structure of each of the devices.

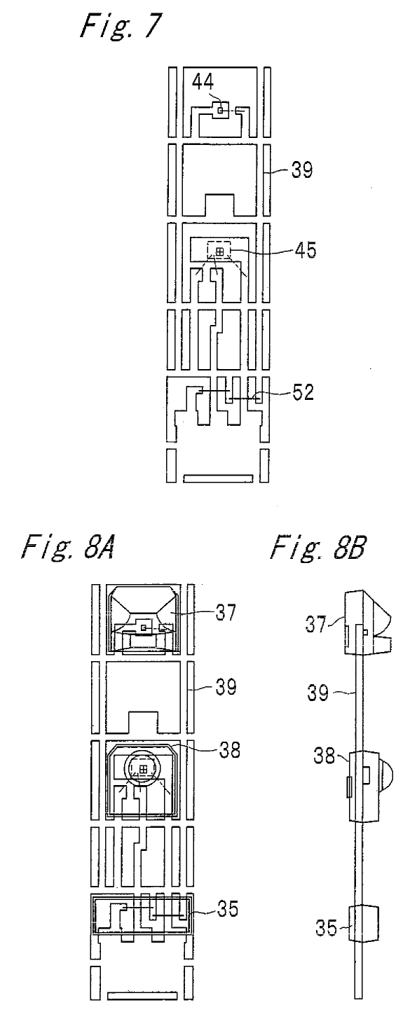

FIG. 7 shows the state that a light-emitting device 44 and a light-receiving device 45 are bonded to a lead frame 39 having a pattern shown in FIG. 6 by die bonding and are wired to the lead frame by wire bonding. The light-emitting device 44 is placed on the upper part, as viewed in the figure, of the lead frame 39, while the light-receiving device 45 is placed on the center part of it. FIG. 7 shows an example of the positional relation between the light-emitting device 44 and the light-receiving device 45, which may be placed in any of the upper part and the center part, as appropriate. In FIG. 7, the light-emitting device 44 and the light-receiving device 45 are shown mounted on the back of the lead frame 39 (backside of the paper) for simple description of subsequent processes. However, the present invention is not limited to this. Furthermore, FIG. 7 shows wire brides comprising wires connecting parts of the lead frame 39, which will be described later.

FIGS. 8A and 8B show the state that the bases of the light-emitting device 44, light-receiving device 45, and connector terminals 33 are encapsulated in light permeable resin. FIG. 8A is a top view, and FIG. 8B is a side view. Also in FIG. 8, the light-emitting device 44 and the light-receiving device 45 are shown mounted on the back of the lead frame 39, for simple description of subsequent processes, like FIG. 7, and lenses (not shown) and the like are also formed on the back of the lead frame 39 in the light-emitting mold 37 and the light-receiving mold 38. In FIG. 8A, the shapes of the connector mold 35, light-emitting mold 37, and light-receiving mold 38 formed on the back of the lead frame 39 are shown with solid lines as if they were seen through the lead frame 39.

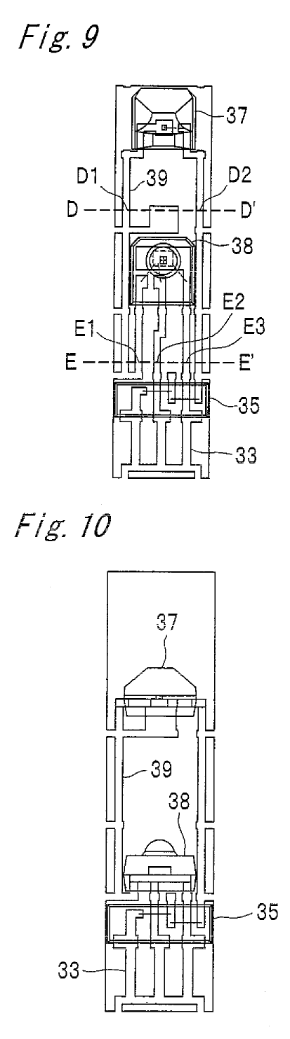

FIG. 9 is a top view of the lead frame 39 after tie-bar cutting. In FIG. 9, the lead frame 39 is cut at peripheries of the molds 35, 37, and 38 and at the connector terminal 33 portion, and thus the entire shape of the connector terminals 33 is formed and forming (folding) in a later process becomes possible. The connector terminals 33 are thus formed in the process of cutting the lead frame 39, so that sides of the connector terminals 33 are in the state that the material of the lead frame 39 is bared. For this reason, coating material for the connector terminals 33 is selected and decided in consideration of the material and the like of a female connector to be connected to the connector terminals 33, and the sides of the connector terminals which are bared are coated with metal in a plating process. Anticorrosive coating is thus applied to the connector terminals 33.

Next, in an area D1 and an area D2 positioned on a broken line D-D′ in FIG. 9 of the lead frame 39, the light-emitting mold 37 is bent upward (in the counterclockwise direction in FIG. 8B) against the direction of extension of the paper to be erected. In addition, in an area E1, an area E2, and an area E3 positioned on a broken line E-E′ in FIG. 9 of the lead frame 39, the light-receiving mold 38 is erected like the light-emitting mold 37. FIG. 10 is a top view of the lead frame 39 in the state that the light-emitting mold 37 and the light-receiving mold 38 have been erected.

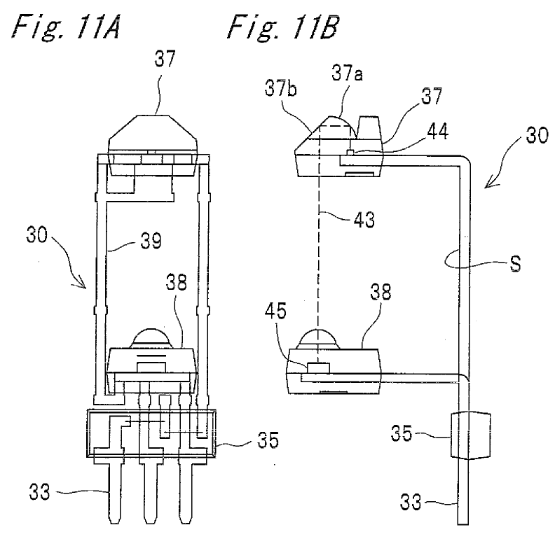

Finally, peripheral parts of the lead frame sheet 39 are cut to divide the lead frame sheet 39 into individual lead frame components, or lead frame assemblies 30 having molds 35, 37, and 38 as shown in FIGS. 11A and 11B. FIG. 11A is a top view, and FIG. 11B is a side view.

In this embodiment, as shown in FIG. 11B, the light-emitting device 44 and the light-receiving device 45 are mounted on the same surface (back) of the lead frame 39, and the light-emitting mold 37 and the light-receiving mold 38 are erected in the same direction against the reference surface S of the lead frame 39, so that the light-emitting device 44 and the light-receiving device 45 are directed in the same direction (upward in FIG. 11B) with respect to the reference surface S of the lead frame 39. For this reason, in order to couple the optical axis of the light-emitting device 44 to the optical axis of the light-receiving device 45, as shown in FIG. 11B, the light-emitting mold 37 made of light permeable resin has two reflecting surfaces 37a and 37b to reflect the light emitted from the light-emitting device 44 to the light-receiving device 45. The two reflecting surfaces are configured to couple the two optical axes 43 by two reflections of the principal ray, and the first reflecting surface 37a of them is shaped like a concave mirror to increase the light collecting efficiency. Such a configuration allows the light-emitting device 44 and the light-receiving device 45 to be mounted on the same surface of the lead frame 39, thereby sufficiently increasing the production efficiency. In addition, the lenses of the molds 37 and 38 made of light permeable resin may also be formed on the same surface of the lead frame 39, so that the molds 37 and 38 can be produced easily.

In this embodiment, the reflecting surfaces 37a and 37b are provided in the light-emitting mold 37. However, the present invention is not limited to this, and the reflecting surfaces may be provided in the light-receiving mold 38 to reflect light incident to the light-receiving device to bend the optical axis 43. In such a case, the light-emitting device 44 and the light-receiving device 45 may be formed on the surface of the lead frame 39.

Next, the second component will be described. FIGS. 12A and 12B are bottom views of the second component and the first component, respectively. As show in FIG. 12a, on the undersurface of the outer case 31 made of light-blocking resin, a light-emitting mold insertion opening 53 in which the light-emitting mold 37 is inserted, a light-receiving mold insertion opening 54 in which the light-receiving mold 38 is inserted, and a connector mold insertion opening 55 in which the connector mold 35 is inserted are formed.

The first component and the second component formed as described above are assembled as follows. As shown in FIG. 13, the light-emitting mold 37, light-receiving mold 38, and connector mold 35 of the first component are inserted in the light-emitting mold insertion opening 53, light-receiving mold insertion opening 54, and connector mold insertion opening 55 of the second component, respectively, and are latched and fixed by the light-emitting mold latching section 41, the light-receiving mold latching section 42, and the connector mold latching section 40, respectively. The state that the first component is accommodated and fixed in the second component in such a manner is as shown in FIGS. 1 and 2.

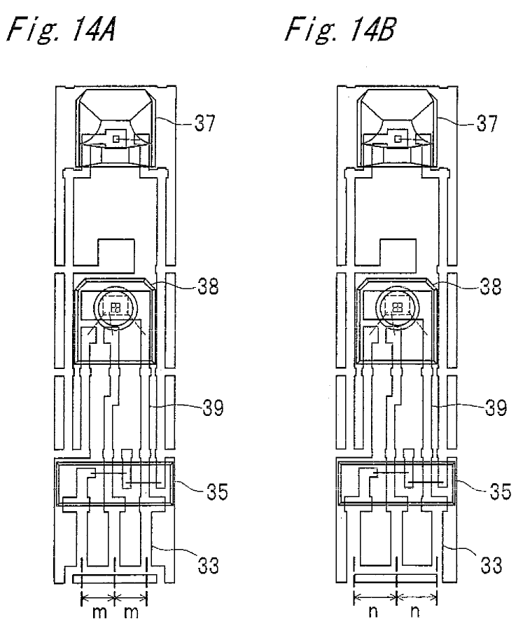

As described with FIG. 9, in this embodiment, the connector terminals 33 are formed in the process of cutting the lead frame 39. FIG. 14A is a top view of a lead frame in which connector terminals 33 are formed with a pitch m, and FIG. 14B is a top view of a lead frame in which connector terminals 33 are formed with a pitch n. As understood from FIGS. 14A and 14b, different shaped sets of connector terminals can be produced from the same lead frames 39 and a common mold can be thus used, thereby achieving significant cost reduction. As a matter of course, connector terminals 33 may be formed on a lead frame 39 from the beginning.

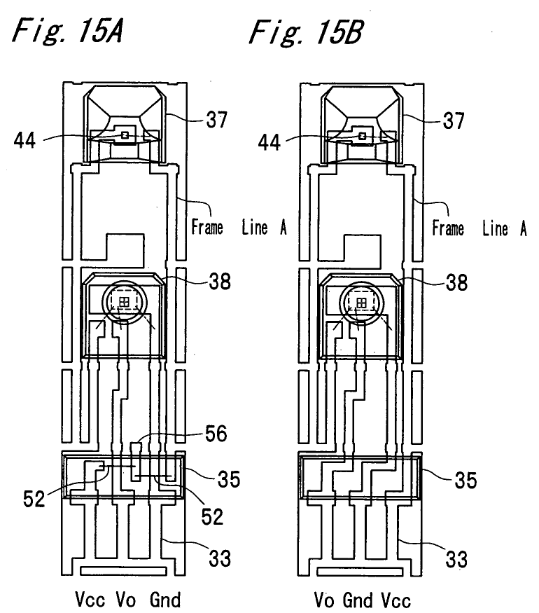

Next, the wire bridges 52 will be described in detail with reference to FIGS. 15A and 15B. FIG. 15A shows the first component in which wire bridges 52 are used in the connector mold 35 and is similar to FIG. 9. A frame line A which starts at the light-emitting device 44 and runs on the right side of the first component in the figure enters straight the connector mold 35, and is connected to the leftmost connector terminal 33 for the voltage Vcc through two wire bridges 52 and a dummy frame 56 in the connector mold 35. In contrast to this, FIG. 15B shows the first component having no wire bridges 52. In this case, the frame line A runs straight on the right side of the first component in the figure, and is then connected to the rightmost connector terminal 33 for the voltage Vcc.

The photo interrupter of this embodiment is an electronic component and is mounted and used on electronic equipment, so that it needs to have pin arrangement required by the electronic equipment. Although there is no ideal pin arrangement, when pin arrangement is designated by electronic equipment, the required pin arrangement can be easily realized by using wire bridges 52.

The photo interrupter having the above configuration operates as follows. As shown in FIG. 2A, light emitted from the light-emitting device 44 is reflected by the reflecting surfaces 37a and 37b of the light-emitting mold 37 as shown in FIG. 11B, and is then released once to the external space of the outer case 31 which is a region for object detection as shown with the optical path 43. The light which has entered the outer case 31 again is detected by the light-receiving device 45 in the light-receiving mold 38. At that time, when an object to be detected (not shown) is inserted in the external space 43 and placed on the optical path 43, the optical path 43 is intercepted by the object, and the light is not detected by the light-receiving device 45. For this reason, the presence of the object can be detected.

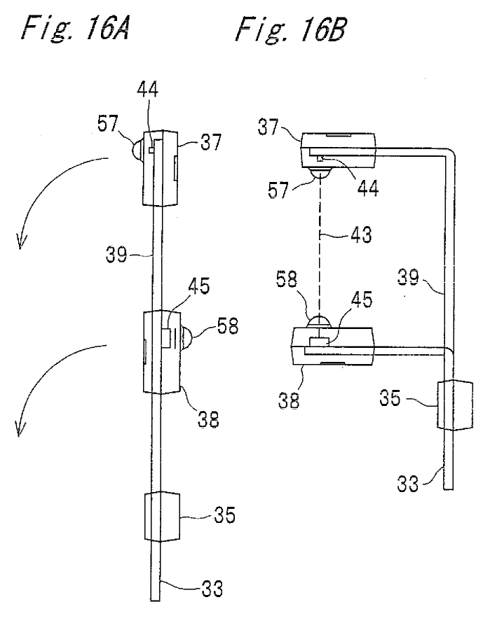

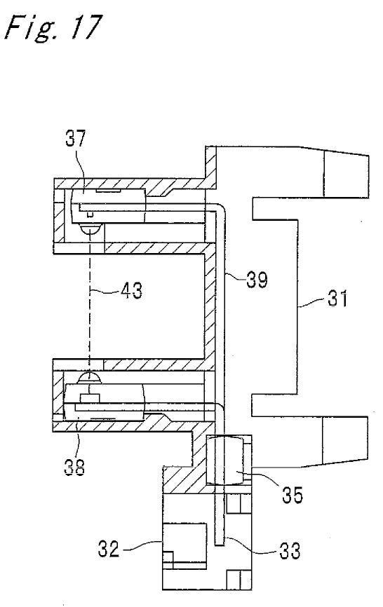

FIGS. 16A, 16B, and 17 show a photo interrupter having another configuration in this embodiment. FIGS. 16A and 16B are side views of the first component, and FIG. 17 is a cross-sectional view of the first component in the state that the first component is engaged with and fixed to the second component. In this configuration, the light-emitting device 44 and the light-receiving device 45 are mounted on different surfaces of the lead frame 39 as understood from FIG. 16A, in contrast to the above configuration shown in FIG. 11. According to this configuration, the light-emitting lens 57 formed in the light-emitting mold 37 and the light-receiving lens 58 formed in the light-receiving mold 38 are formed on different surfaces. When the light-emitting mold 37 and light-receiving mold 38 of the first component configured like this are erected in the same direction as the counterclockwise direction as shown in FIG. 16A at predetermined positions, like the above the configuration shown in FIG. 11, the light-emitting device 44 and the light-emitting lens 57, and the light-receiving device 45 and the light-receiving lens, are placed to face each other, respectively.

The first component is fixed to the outer case 31 by a method similar to that for the above configuration shown in FIG. 13 to obtain a structure as shown in FIG. 17. For this reason, the light-emitting device 44 and the light-receiving device 45 face each other, so that the first reflecting surface 37a and the second reflecting surface 37b in the above configuration shown in FIG. 11 are not necessary. Thus, the photocoupling efficiency (ratio of the amount of emitted light to the amount of received light) can be increased accordingly. The photo interrupter of this configuration is complicate in the production process as compared with the above configuration shown in FIG. 11, but has high photocoupling efficiency, so that a low out put and low cost light-emitting device and a low light-receiving area and low cost small light-receiving device 45 can be used.

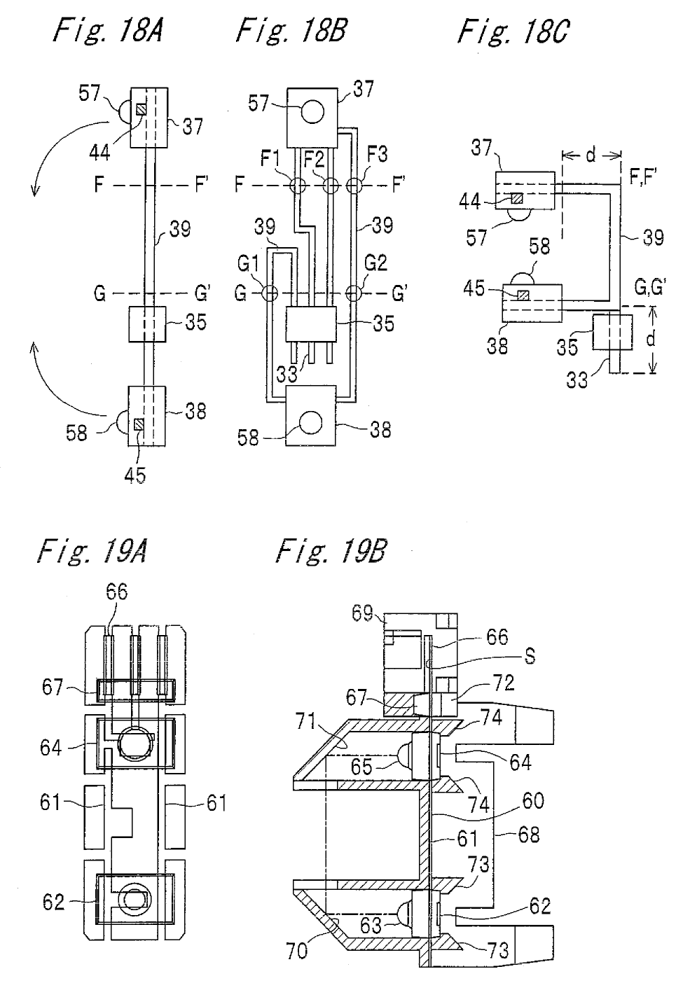

FIGS. 18A to 18C show a photo interrupter having still another configuration in this embodiment. FIGS. 18A and 18B are a side view and a top view, respectively, of a lead frame 39 before being bent, and FIG. 18C is a side view of the lead frame 39 after being bent, showing the state that the light-emitting mold 37 and the light-receiving mold 38 stand erect. In this configuration, the light-emitting device 44 and the light-receiving device 45 are mounted on the same surface of the lead frame 39, and the light-emitting lens 57 of the light-emitting mold 37 and the light-receiving lens 58 of the light-receiving mold 38 are also formed on the same surface. Furthermore, the connector mold 35 in this configuration is different in position as compared with the above two configurations, and is formed between the light-emitting mold 37 and the light-receiving mold 38. As shown in FIG. 18, parts of the lead frame 39 extending from the light-receiving mold 38 pass either side of the connector mold 35 and are connected with the light-emitting mold 37 and the connector mold 35 in an appropriate manner.

In the first component having a configuration as described above, the light-emitting mold 37 is erected in areas F1, F2, and F3 positioned on a broken line F-F′ shown in FIGS. 18A and 18B by turning in a counterclockwise direction shown in FIG. 18A. In contrast to this, the light-receiving mold 38 is erected by turning in a clockwise direction (a direction opposite to the direction for the light-emitting mold 37) shown in FIG. 18A in areas G1 and G2 positioned on a broken line G-G′. In this case, the light-receiving mold 38 passes above the connector mold 35 and moves to the upright position. For this reason, a structure in which the light-emitting device 44 and the light-receiving device 45 face each other can be obtained as shown in FIG. 18C.

In this configuration, in order that the light-receiving mold 38 passes above the connector mold 35 and stands erect, the light-receiving mold 38 is on the same side as the connector mold against the broken line G-G′ where the lead frame 39 is bent, and is outside the connector mold 35, as shown in FIGS. 18A and 18B. For this reason, the height of the optical axis of the light-receiving mold 38 is larger than the sum “d” of the length of the connector mold 35 and the length of the connector terminals 33. In general, a connector section 32 is standardized goods, and the size of it has been decided to some extent. Thus, when a connector section 32 to be used has been decided, the length “d” is decided to some extent, and the height of the optical axis is also decided according to the length “d”. For this reason, when the height of the optical axis is small, the length of the connector terminals 33 is short and the connector mold 35 is small, so that there will be problems on the engaging strength of the connector section 32 and the like. Thus, this configuration is suitable for relatively medium and large photo interrupters with a sufficiently high optical axis, and for very small photo interrupters in which a large force is not applied to the connector section 35.

As described above, in this embodiment, a photo interrupter consists of a “first component” comprising a lead frame on which the light-emitting mold 37, the light-receiving mold 38, and the connector mold 35 are formed, and a “second component” comprising an outer case 31 formed integrally with a connector section 32. The light-emitting mold 37, light-receiving mold 38, and connector mold 35 of the first component are inserted in a light-emitting mold insertion opening 53, a light-receiving mold insertion opening 54, and a connector mold insertion opening 55 formed in the second component, respectively, thereby inserting (press-fitting) the first component in the second component, and the light-emitting mold 37, light-receiving mold 38, and connector mold 35 of the first component are then latched by the light-emitting mold latching section 41, light-receiving mold latching section 42, and connector mold latching section 40 of the second component. Thus, the first component is accommodated in and fixed to the second component.

Consequently, a connector-equipped photo interrupter which comprises a few components and is assembled easily can be proposed. Furthermore, a photo interrupter which is reliable because of having no electrical contacts can be proposed.

### Second Embodiment

FIGS. 19A and 19B show the configuration of a photo interrupter according to a second embodiment. FIG. 19A is a top view of a first component, FIG. 19B is a cross-sectional view of the photo interrupter in which the first component is engaged with and fixed to a second component.

In this embodiment, as shown in FIG. 19A, a light-emitting device (not shown) and a light-receiving device (not shown) are mounted on the same surface (the front side of the paper) of a lead frame 61, and a light-emitting lens 63 of a light-emitting mold 62 and a light-receiving lens 65 of a light-receiving mold 64 are formed on the same surface of the lead frame 61. As in the case of the first embodiment, a connector mold 67 is formed so as to cover the bases of connector terminals 66.

In this embodiment, as shown in FIG. 19B, in contrast to the first embodiment, the light-emitting mold 62 and the light-receiving mold 64 are not erected against the reference surface S, but are inserted in their non-erected state in, engaged with, and fixed to an outer case 68 which is formed integrally with a connector section 69. Inside the outer case 68, a first reflecting surface 70 is formed in a position facing the light-emitting lens 63, and a second reflecting surface 71 is formed in a position facing the light-receiving lens 65. Light emitted upward from the light-emitting device is reflected by the first reflecting surface 70 and is then reflected by the second reflecting surface 71 to enter the light-receiving device. The reference numeral 72 denotes a connector mold latching section, 73 denotes a light-emitting mold latching section, and 74 denotes a light-receiving mold latching section.

With the above configuration, the process of erecting the light-emitting mold 62 and the light-receiving mold 64 against a surface (reference surface) S of the lead frame become unnecessary, and it is not required to keep patterns in portions for the erection on the lead frame 61, so that an area required per one device of the lead frame 61 can be reduced, as compared with the first embodiment.

### Third Embodiment

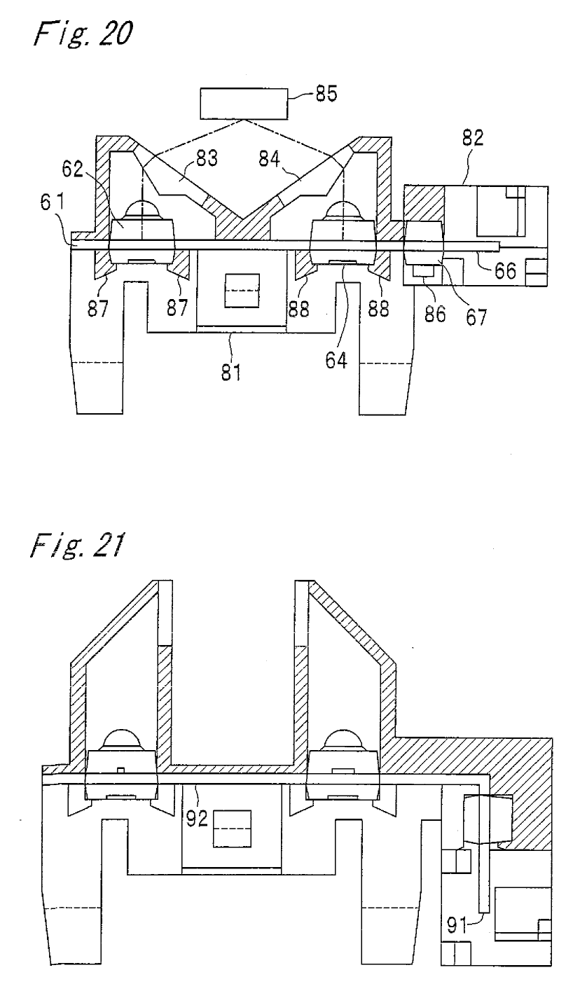

FIG. 20 shows the configuration of the photo interrupter of a third embodiment. In this embodiment, the same numerals are attached to the same portions as those of the second embodiment to omit the description about them, and only portions different from the second embodiment will be described.

In this embodiment, a first component, or lead frame assembly 60 having a lead frame 61, a light-emitting mold 62, a light-receiving mold 64, and a connector mold 67 has the same configuration as that of the second embodiment. However, the configuration of a second component comprising an outer case 81 integrally formed with a connector section 82 is different from that of the second embodiment. As shown in FIG. 20, in the outer case 81, reflecting surfaces for reflecting light emitted from the light-emitting device as in the case of the second embodiment are not formed. Instead, the outer case 81 has a cross-section shaped like a letter M, and one of two inclined planes constituting the top of the outer case 81 has an emitted light refractor 83 which refracts light from the light-emitting device to release it in an oblique direction to a point on the center line between the two inclined planes. On the other hand, the other one of the two inclined planes constituting the top has an incident light refractor 84 which refracts oblique light from the point to allow the light to enter the light-receiving device.

In the above configuration, light emitted from the light-emitting mold 62 is refracted by the emitted light refractor 83 and is released in an oblique direction to a point on the center line, where the light is reflected by an object to be detected 85, and is then refracted by the incident light refractor 84 to enter the light-receiving mold 64. With such a configuration, not only a transmission photo interrupter as in the cases of the first and second embodiments but also a reflection photo interrupter can be realized, so that the height of a photo interrupter can be significantly decreased as compared with the first embodiment and the second embodiment. In FIG. 20, the reference numeral 86 denotes a connector mold latching section, 87 denotes a light-emitting mold latching section, and 88 denotes a light-receiving mold latching section.

In each of the embodiments described above, the direction of insertion of the female connector can be changed by bending the connector terminals 91 against the main body of the lead frame 92 as shown in FIG. 21.

As described above, a connector-equipped photo interrupter having a structure shown in each of the embodiments described above can be made by assembling roughly divided two components, that is, a first component including a lead frame on which the molds are formed, and a second component including an outer case integrally formed with a connector section. Thus, a connector-equipped photo interrupter which consists of a few components and can therefore be assembled easily is provided. Furthermore, a photo interrupter which is reliable because of having no electrical contacts is provided.

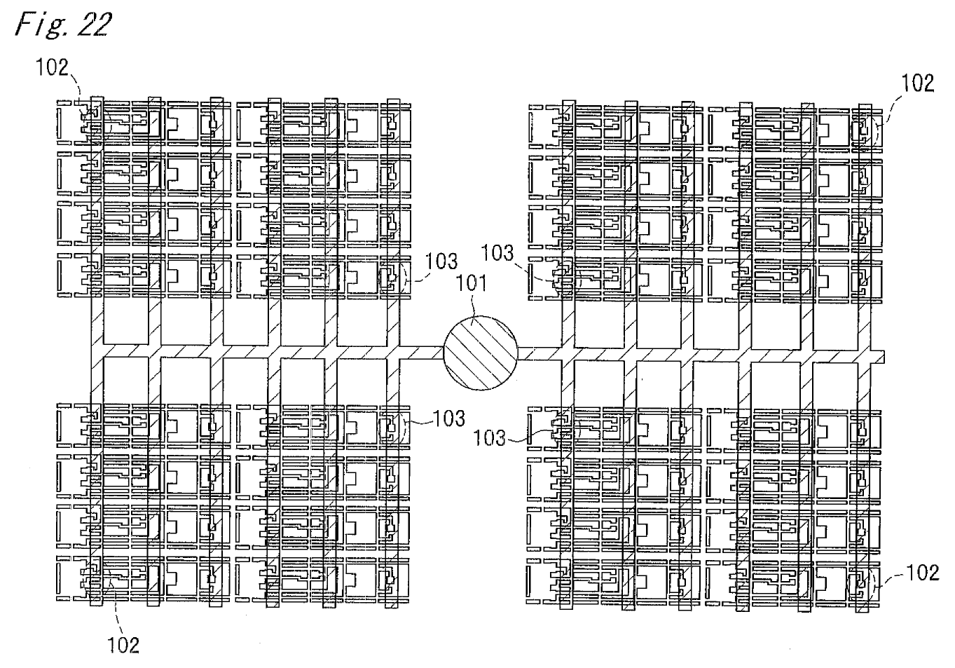

When photo interrupters of any of the embodiments described above are formed, it is desirable that as many photo interrupters as possible are mounted on one lead frame sheet because reduction of a cost per device is required. Furthermore, as shown in FIG. 22, it is desirable that two or more lead frame sheets are processed in one molding process. However, when light-emitting mold 37, 62 each encapsulating a light-emitting device 44 in resin, light-receiving molds 38, 64 each encapsulating a light-receiving device 45 in resin, connector molds each encapsulating part of connector terminals 33 in resin are formed in one molding process for a plurality of lead frame sheets arranged like a matrix, many molds 37, 38, 35; 62, 64, 67 are formed at the same time. In this case, the difference between the longest one 102 of distances from the resin supply source 101 to molds 37, 38, 35; 62, 64, 67 of photo interrupters and the shortest one of the distances is large, which causes a difference in sealing property and a difference in mold shape between packages. For this reason, the production stability such as the resin fluidity may decrease.

Furthermore, in order that gold wires or the like connecting light-emitting devices 44 and light-receiving devices to lead frames 39 be not broken by injected light permeable resin, light permeable resin having high fluidity is usually used for light-emitting molds 37, 62 and light-receiving molds 38, 64. The light permeable resin having high fluidity generally has a low mechanical strength. On the other hand, when connector molds 35, 67 are made of the same resin as that for light-emitting molds 37, 62 and light-receiving molds 38, 64 as shown in FIG. 22, the connector molds 35, 67 are also made of light permeable resin having high fluidity. Therefore, mechanical strengths of the connector molds 35, 67 decrease. As a result, it is expected that when a female connector (not shown) is extracted from and inserted in connector terminals 33 of a photo interrupter repeatedly, the photo interrupter is broken because the strength of the connector mold 35, 67 is insufficient.

### Fourth Embodiment

In this embodiment, a method is described which increases the strength of a photo interrupter to make it more reliable, and improves the production stability, while maintaining the features of each of the embodiments described above.

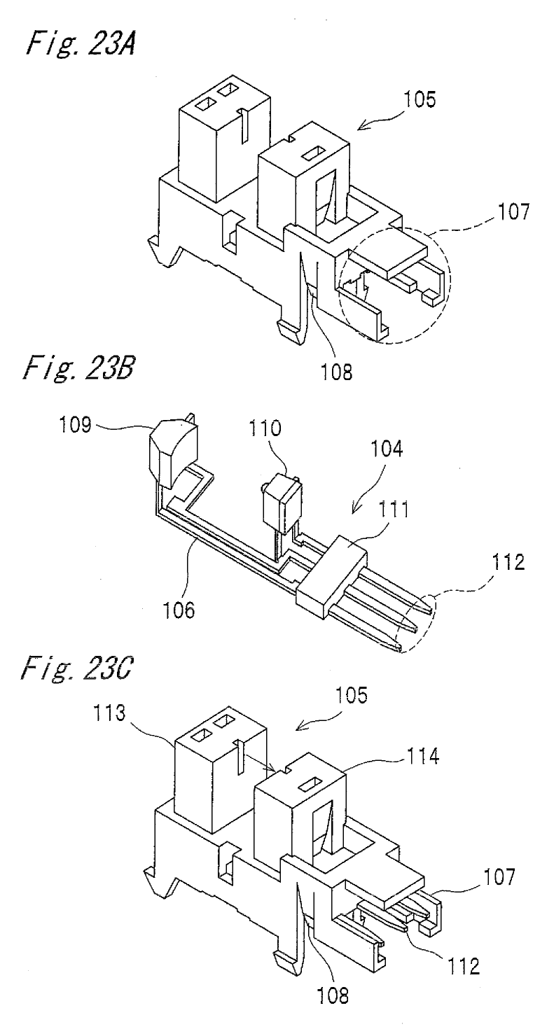

FIGS. 23A to 23C are perspective views of components of the photo interrupter of this embodiment. FIG. 23A shows an outer case 105, FIG. 23B shows a lead frame assembly (single piece) 104, and FIG. 23C shows the state that the outer case 105 and the lead frame assembly 104 are assembled. The outline of this photo interrupter is almost identical to that of the photo interrupter shown in FIGS. 1 and 2 of the first embodiment.

The configuration of the photo interrupter of this embodiment is almost identical to that of the photo interrupter shown in FIGS. 1 and 2 of the first embodiment, and will be simply described below. As shown in FIG. 23A, a connector section 107 in which a female connector (not shown) will be inserted is formed on the outer case 105, comprising a connector integrated outer case. In addition, two latching sections 108 for latching the lead frame assembly 104 accommodated in the outer case 105 are formed in positions symmetric with respect to the axis in the outer case. Furthermore, the lead frame 106 has been made into such a shape that the light-emitting mold 109 and the light-receiving mold 110 face each other and the connector terminals 112 protrude from the connector mold 111, as shown in FIG. 23B, through a tie-bar cutting process, a lead forming process, and a single piece cutting process, after molding. The lead frame assembly 104 is inserted in the outer case 105 from underneath (see FIG. 23A), and thereby the connector mold 111 of the lead frame assembly 104 is latched at both sides by the latching sections 108 of the outer case 105 to assemble the lead frame assembly 104 and the outer case 105 as shown in FIG. 23C. Although any concrete configuration of the latching section 108 does not appear in FIG. 23, the latching section 40 has a configuration similar to that of the connector mold latching section 40 shown in FIG. 2 of the first embodiment. In a photo interrupter assembled in this manner, there is an optical axis of light from a light-emitting device (not shown) between two protruding components 113 and 114 shaped like a tower, and the presence or absence of an object between the protruding components 113 and 114 can be detected.

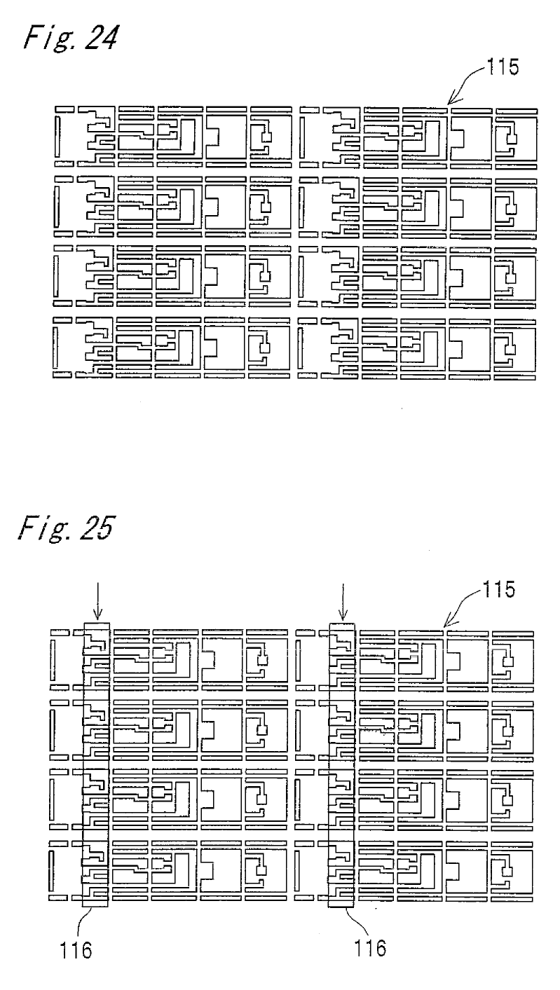

Next, the method of manufacturing a photo interrupter of this embodiment will be described. FIG. 24 shows an example of a pattern of a lead frame sheet 115, in which patterns for lead frames (single pieces) 106 for photo interrupters are arranged like a matrix. In FIG. 24, 4 by 2 patterns are arranged, but the number of patterns and the pattern arrangement may be set freely according to the conditions of the production facilities and the like. In four patterns aligned in a row of 4 by 2 patterns of lead frames 106, areas for formation of light-emitting molds 109 are arranged straight in the longitudinal direction in the figure. Likewise, areas for formation of light-receiving molds 110 and areas for formation of connector molds 111 are also arranged in a row in the same direction.

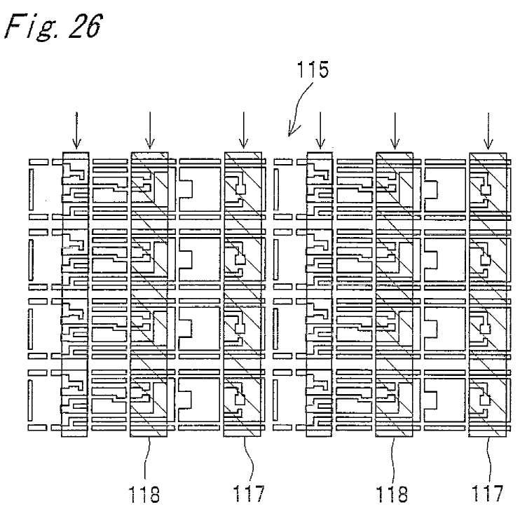

For the lead frame sheet 115 configured as described above, as shown in FIG. 25, resin is injected by means of molding in the direction of the arrow into two sets of connector mold formation areas 116 each arranged in a row to form connector molds 111. As described above, in this embodiment, only the connector molds 111 are formed, so that resin specialized for functions required for the connector molds 111 can be selectively used. Next, as shown in FIG. 26, translucent molding resin is injected by means of transfer molding in the direction of the arrow into two sets of light-emitting mold formation areas 117 each arranged in a row and two sets of light-receiving mold formation areas 118 each arranged in a row to form light-emitting molds 109 and light-receiving molds 110 at the same time.

At that time, in the connector molding process shown in FIG. 25, the strengths of the connector molds 111 can be increase by mixing fillers and the like into the molding resin as appropriate. Furthermore, although the order of the process of formation of connector mold 111 and the process of formation of light-emitting molds 109 and light-receiving molds 110 is described as that the process of formation of connector mold 111 is performed before the process of formation of light-emitting molds 109 and light-receiving molds 110 as an example, any order of the processes may be adopted.

In either case, the connector molds 111 are formed in a molding process different from that for the light-emitting molds 109 and the light-receiving molds 110, so that the pattern of routing the molding resin supply passages can be simplified, the difference between the longest one of distances from the resin supply source (not shown) to the molds 109, 110, and 111 of the photo interrupters and the shortest one of the distances can be reduced, and the number of photo interrupters formed at the same time can be reduced. For this reason, the pouring of the molding resins can be stabilized, and the production stability can be thus improved.

The lead frame sheet 115 into which molding resins have been poured as described above are cut into individual ones through usual processes of tie-bar cutting, lead forming, and single piece cutting to form single-piece lead frame assemblies 104 shaped as shown in FIG. 23B.

The photo interrupter of this embodiment is fixed to an external substrate (not shown) or the mounting plate of external equipment, when put to use, by inserting four hooks 119 formed on the four bottom corners of the outer case 105 to the external substrate or the mounting plate. A female connector 120 matching the shape of the connector section 107 is then inserted in the connector section 107 to electrically connect the female connector 120 to the connector terminals 112. Wiring 121 of a given length extends from the female connector 120, and a signal representing the presence or absence of the intercepting object from the photo interrupter is input to electronic equipment (not shown) which is connected to the end of the wiring 121. On the basis of the signal, the electronic equipment is controlled.

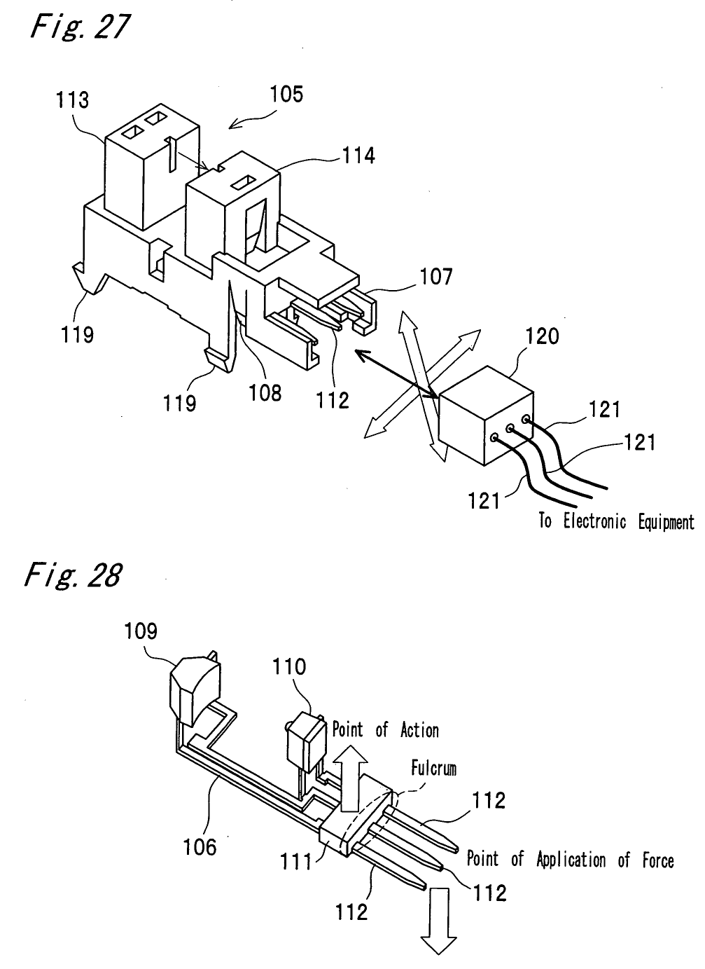

When the female connector 120 is inserted in or extracted from the connector section 107 as indicated by the black arrow in FIG. 27, an external force (indicated by an outline arrow) is applied more or less to the axis of the photo interrupter in the vertical direction. In particular, when the female connector is extracted from or inserted in the connector section 107 by hand, the influence of the external force is large, and a large force acts the inside of the connector mold 111, with a power point on an end of the connector terminals 112, a supporting point on the base of the connector terminals 112, and a point of action on the inside of the connector mold 111.

In that case, when the connector mold 111 has been made of light permeable resin (particularly high fluidity light permeable resin) like the light-emitting mold 109 and the light-receiving mold 110 in which importance is put on the optical characteristics, the connector mold 111 may be broken by a large force acting the inside of the connector mold 11. However, in this embodiment, the connector mold 111 has been made of molding resin having a high mechanical strength, in contrast to the light-emitting mold 109 and the light-receiving mold 110, in a molding process which is different from that for the light-emitting mold 109 and the light-receiving mold 110. Thus, the connector mold 111 can be prevented from being broken by the force acting the connector mold 11 at extraction or insertion of the female connector 120. In addition, the mechanical strength of the molding resin can be more increased by mixing fillers into the molding resin as appropriate to more improve the reliability.

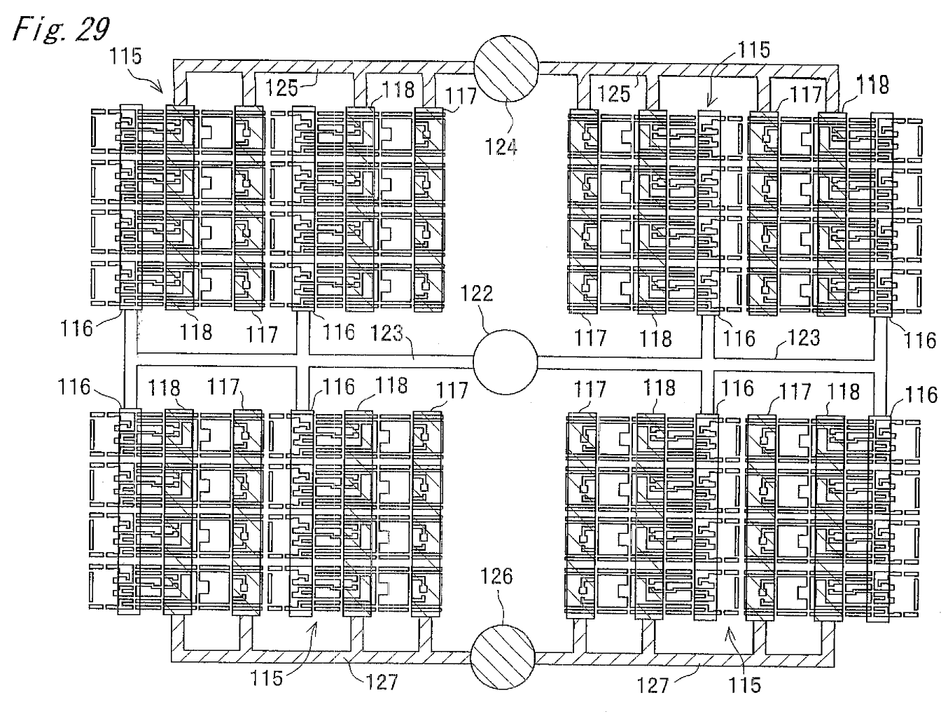

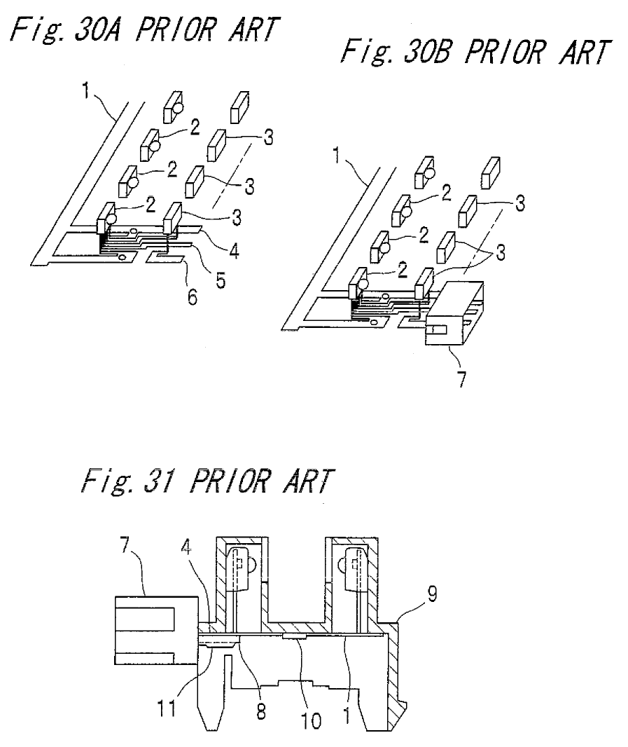

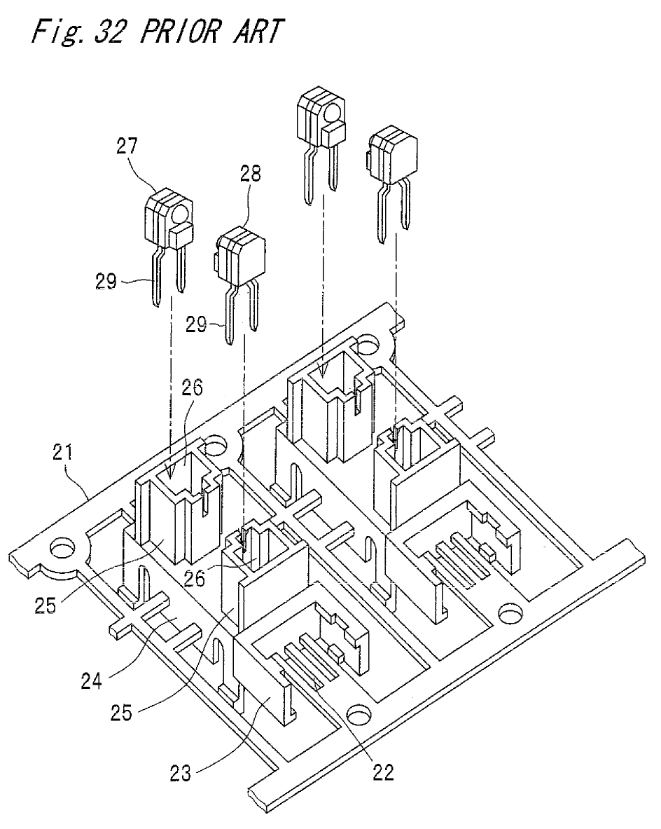

FIG. 29 shows the manufacturing method which is different from that in FIGS. 25 and 26 for the photo interrupter of this embodiment. In FIG. 29, four lead frame sheets 115 having a pattern shown in FIG. 24 are arranged like a matrix, as an example. As in the case of FIG. 24, areas for formation of light-emitting molds, areas for formation of light-receiving molds 110, and areas for formation of connector molds 111 are each arranged in a row in the longitudinal direction in the figure. At the center of the four lead frame sheets 115, a first resin supply source which supplies molding resin to eight sets of connector mold formation areas 116 each arranged in a row is placed. The first resin supply source 122 is connected with the connector mold formation areas 116 through runners 123.

Furthermore, on the upper part of the area in which the four lead frame sheets 115 are arranged like a matrix, a second resin supply source 124 is placed which supplies molding resin to four sets of light-emitting mold formation areas 117 which are each arranged in a row, and four sets of light-receiving mold formation areas 118 which are each arranged in a row, in two lead frame sheets 115. The second resin supply source 124 is connected with the light-emitting mold formation areas 117 and the light-receiving mold formation areas 118 through runners 125. Likewise, on the lower part of the area in which the four lead frame sheets 115 are arranged like a matrix, a third resin supply source 126 is placed which supplies molding resin to four sets of light-emitting mold formation areas 117, and four sets of light-receiving mold formation areas 118, in two lead frame sheets 115. The third resin supply source 126 is connected with the light-emitting mold formation areas 117 and the light-receiving mold formation areas 118 through runners 127.

In other words, in this embodiment, the first resin supply source 122 constitutes the second resin supply source, while the second resin supply source 124 and the third resin supply source 126 constitute the first resin supply source.

According to the configuration in FIG. 29, molding resin specialized for functions of connector molds 111 can be selectively supplied from the first resin supply source 122. Furthermore, molding resin specialized for functions of light-emitting molds 109 and light-receiving molds 110 can be selectively supplied from the second resin supply source 124 and the third resin supply source 126. In other words, light-blocking resin in which fillers are mixed can be supplied from the first resin supply source. Thus, molding resin for connector molds 111 and molding resin for light-emitting molds 109 and light-receiving molds 110, which are different in characteristic from each other, can be supplied at the same time. Consequently, as compared with the case that light-emitting molds 109, light-receiving molds 110, and connector molds 111 are made of the same resin at the same time, the difference between photo interrupters in sealing property and mold shape as described above can be decreased, so that stable production can be performed and reliable photo interrupters can be achieved.

As described above, in the photo interrupter of this embodiment, the connector mold 111 is made of molding resin supplied through a molding resin supply passage which is different from that for the light-emitting mold 109 and the light-receiving molds 110, so that light-blocking resin in which, for example, fillers and the like are mixed can be used as molding resin for the connector mold 111, thereby increasing the strength of the connector mold 111. Thus, the reliability to a twisting stress and the like in the case that a female connector 120 is extracted from or inserted in the connector section 107 can be extremely improved. In addition, the pattern of routing the runners 123, 125, and 127 which are the molding resin supply passages can be simplified, and thereby the pouring of the molding resins can be stabilized to improve the production stability.

The photo interrupter of each of the embodiments described above is used much effectively as a paper detecting device of a printer, a copying machine, or the like. Electronic equipment such as a printer or a copying machine has a paper feeding function, and it can be found, by mounting the photo interrupter on each paper feeding mechanism, that a paper has been fed up to which paper feeding mechanism and has been processed, and the process of the electronic equipment can be executed smoothly. Furthermore, the photo interrupter is much effective also when a paper jam and the like has occurred because it is able to inform the user that which paper feeding mechanism has a paper jam.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A photo interrupter, comprising:
a lead frame assembly having a lead frame, a light-emitting device and a light-receiving device which are mounted on the lead frame and each encapsulated in a light permeable resin, and a connector terminal for external connection provided at an end of the lead frame; and
an outer case for accommodating the lead frame assembly so as to be integrated with the lead frame assembly, the outer case being made of light-blocking resin and having a connector section,
wherein the connector terminal is adapted to be accommodated in the connector section when the lead frame assembly is accommodated in the outer case;
wherein the lead frame assembly has a connector mold made of a resin, the connector mold covering at least part of the connector terminal; and
wherein at least any one of the outer case and the connector mold is provided with a latching section for latching the connector mold to the outer case.

2. A photo interrupter as claimed in claim 1, wherein a light-emitting mold having the light-emitting device encapsulated in light permeable resin and a light-receiving mold having the light-receiving device encapsulated in light permeable resin stand erect against a reference surface of the lead frame.

3. A photo interrupter as claimed in claim 2, wherein:
the light-emitting device and the light-receiving device are mounted on a same surface of the lead frame;
the light-emitting mold and the light-receiving mold stand erect on one side of the reference surface of the lead frame; and
any one of the light-emitting mold and the light-receiving mold has a light reflecting surface for turning direction of an optical path of light to be released from the light-emitting mold or direction of an optical path of light having entered the light-receiving mold such that light emitted from the light-emitting device enters the light-receiving device.

4. A photo interrupter as claimed in claim 2, wherein:
the light-emitting device and the light-receiving device are mounted on opposed first and second surfaces of the lead frame, respectively;
the light-emitting mold and the light-receiving mold stand erect on one side of the reference surface of the lead frame; and
the light-emitting device and the light-receiving device face each other.

5. A photo interrupter as claimed in claim 2, wherein:
the light-emitting device and the light-receiving device are mounted on a same surface of the lead frame;
the light-emitting mold and the light-receiving mold stand erect on one side of the reference surface of the lead frame;
and
the light-emitting device and the light-receiving device face each other.

6. A photo interrupter as claimed in claim 1, wherein:
connector terminals mechanically separated from each other exist in the connector mold; and
the mechanically separated connector terminals are wired by wire bonding and electrically connected with each other.

7. A photo interrupter as claimed in claim 1, wherein a connector mold fixing section for fixing the connector mold to the outer case is provided on the outer case on at least one of opposite sides of the connector mold in a direction of extension of the connector terminal.

8. A photo interrupter as claimed in claim 1, further comprising a lead frame fixing column which is formed on the outer case and extends in a direction orthogonal to a direction of extension of a main body of the lead frame to fix the main body of the lead frame.

9. A photo interrupter as claimed in claim 1, further comprising:
a groove-like notch formed in the connector mold; and
a connector mold latching section shaped like a column which is provided on an inner surface of the outer case and is engaged with the notch to latch the connector mold.

10. A photo interrupter as claimed in claim 1, wherein:
the light-emitting device and the light-receiving device are mounted on a same surface of the lead frame; and
the photo interrupter further comprises:
a first reflecting surface which is provided on an inner surface of the outer case in a position facing the light-emitting device for reflecting light emitted from the light-emitting device toward the light-receiving device, and
a second reflecting surface which is provided on the inner surface of the outer case in a position facing the light-receiving device for reflecting light from the first reflecting surface to the light-receiving device; and
an optical axis of the light-emitting device and an optical axis of the light-receiving device are coupled by the first reflecting surface and the second reflecting surface.

11. A photo interrupter as claimed in claim 1, wherein:
the light-emitting device and the light-receiving device are mounted on a same surface of the lead frame; and
the outer case is provided with:
an emitted light refractor in a position facing the light-emitting device for refracting light emitted from the light-emitting device to direct the light to an object to be detected, and
an incident light refractor in a position facing the light-receiving device for refracting light reflected by the object to be detected to direct the light to the light-receiving device.

12. A photo interrupter as claimed in claim 1, wherein:
the resin which the connector mold is made of is a same light permeable resin as the light permeable resin encapsulating the light-emitting device and the light-receiving device.

13. A photo interrupter as claimed in claim 1, wherein:
the resin which the connector mold is made of is a light permeable resin different from the light permeable resin encapsulating the light-emitting device and the light-receiving device.

14. A photo interrupter as claimed in claim 1, wherein fillers are mixed in the resin which the connector mold is made of.

15. A method of manufacturing a photo interrupter of claim 1, comprising steps of:
mounting a light-emitting device and a light-receiving device on a lead frame which is formed with connector terminals and performing predetermined wiring for the light-emitting device and the light-receiving device;
forming a light-emitting mold and a light-receiving mold by encapsulating the light-emitting device and the light-receiving device on the lead frame in a light permeable resin;
forming a connector mold by encapsulating part of the connector terminal in a resin;
forming an outer case having a connector section at an end thereof by injection molding;
and
inserting in the outer case the lead frame on which the light-emitting mold, the light-receiving mold, and the connector mold are formed such that the connector terminals of the lead frame are positioned in the connector section of the outer case, thereby accommodating the lead frame in the outer case,
wherein any one of said step of forming an outer case and said step of forming a connector mold comprises forming a latching section for latching the connector mold to the outer case; and
wherein the connector mold is latched and fixed, when accommodating the lead frame in the outer case, to the outer case by the latching section formed on at least one of the outer case or the connector mold.

16. A method of manufacturing a photo interrupter as claimed in claim 15, wherein:
said step of mounting a light-emitting device and a light-receiving device and performing predetermined wiring comprises mounting a plurality of light-emitting devices and a plurality of light-receiving devices on a lead frame sheet in which two or more sets of connector terminals are formed and performing predetermined wiring for the light-emitting devices and the light-receiving devices;
said step of forming a light-emitting mold and a light-receiving mold comprises forming light-emitting molds and light-receiving molds for the respective light-emitting devices and the respective light-receiving devices;
said step of forming a connector mold comprises forming connector molds for the respective sets of connector terminals;
the method further comprising:
cutting tie bars placed at least on the peripheries of the light-emitting molds and the light-receiving molds; and
cutting tie bars by which devices each having the light-emitting mold, the light-receiving mold, the connector mold, and the connector terminals are connected and fixed to a main body of the lead frame sheet to divide the lead frame sheet into the individual devices,
wherein the connector terminals are formed into their final shapes in any one of said step of cutting tie bars placed at least on the peripheries of the light-emitting molds and the light-receiving molds or said step of cutting tie bars by which devices each are connected and fixed to the main body of the lead frame sheet to divide the lead frame sheet into the individual devices.

17. A method of manufacturing a photo interrupter as claimed in claim 16, further comprising a plating step of covering the connector terminals with metal performed after the step of cutting tie bars including forming the connector terminals into their final shapes.

18. A method of manufacturing a photo interrupter as claimed in claim 15, wherein:
said step of forming a light-emitting mold and a light-receiving mold and said step of forming a connector mold are performed together in a same process by using a same light permeable resin material.

19. A method of manufacturing a photo interrupter as claimed in claim 15, wherein:
said step of forming a light-emitting mold and a light-receiving mold and said step of forming a connector mold are performed separately by using different resin materials.

20. A method of manufacturing a photo interrupter as claimed in claim 15, wherein:
said step of forming a light-emitting mold and a light-receiving mold and said step of forming a connector mold are performed in a same process, in which process a light permeable resin supplied from a first resin supply source is used for the light-emitting mold and the light-receiving mold, while a resin different from the light permeable resin supplied from a second resin supply source is used for the connector mold.

21. Electronic equipment comprising a photo interrupter of claim 1.
